(19) United States
(12) Patent Application Publication
(10) Pub. No.: US 2026/0305293 A1
(43) Pub. Date: Oct. 1, 2026

(54) THREE-DIMENSIONAL MEMORY DEVICE WITH INTEGRATED WORD LINE AND CONTACT VIA STRUCTURES AND METHOD OF MAKING THEREOF

(71) Applicant: Sandisk Technologies, Inc., Milpitas, CA (US)

(72) Inventors: Ruogu Matthew ZHU, San Jose, CA (US); Koichi MATSUNO, Fremont, CA (US)

(21) Appl. No.: 19/091,391

(22) Filed: Mar. 26, 2025

(51) Int. Cl. H01L 23/522; H01L 21/762; H01L 21/768; H01L 23/528; H10B 41/20; H10B 41/35; H10B 43/20; H10B 43/35

(52) U.S. Cl. CPC H10W 20/42; H10B 41/20; H10B 41/35; H10B 43/20; H10B 43/35; H10W 10/014; H10W 10/17; H10W 20/056; H10W 20/089; H10W 20/435

(57) ABSTRACT

A memory device includes integrated word line and contact via structures each including a respective horizontally-extending word line, a respective contact via structure, and a respective lateral connection strip connecting the respective horizontally-extending word line and the respective contact via structure; insulating layers vertically spaced apart from each other and interlaced with the horizontally-extending word lines to provide a vertically alternating sequence of the insulating layers and the horizontally-extending word lines, memory openings vertically extending through the vertically alternating sequence, and memory opening fill structures located in the memory openings.

### FIELD

The present disclosure relates generally to the field of semiconductor devices, and particularly to a three-dimensional memory device including integrated word line and via structures and methods for forming the same.

### BACKGROUND

A three-dimensional memory device including a three-dimensional vertical NAND strings having one bit per cell is disclosed in an article by T. Endoh et al., titled “Novel Ultra High Density Memory With A Stacked-Surrounding Gate Transistor (S-SGT) Structured Cell”, IEDM Proc. (2001) 33-36.

### SUMMARY

According to an aspect of the present disclosure, a memory device includes integrated word line and contact via structures each comprising a respective horizontally-extending word line, a respective contact via structure, and a respective lateral connection strip connecting the respective horizontally-extending word line and the respective contact via structure; insulating layers vertically spaced apart from each other and interlaced with the horizontally-extending word lines to provide a vertically alternating sequence of the insulating layers and the horizontally-extending word lines; memory openings vertically extending through the vertically alternating sequence; and memory opening fill structures located in the memory openings, wherein each of the memory opening fill structures comprises a respective vertical stack of memory elements located at levels of the horizontally-extending word lines and a vertical semiconductor channel.

According to another aspect of the present disclosure, a method of forming a memory device comprises: forming an alternating stack of insulating layers and sacrificial material layers over a substrate; forming memory openings through the alternating stack; forming memory opening fill structures in the memory openings, wherein each of the memory opening fill structures comprises a respective vertical stack of memory elements and a vertical semiconductor channel; forming dual-width lateral isolation trenches through the alternating stack, wherein each of the dual-width lateral isolation trenches comprises a respective wide lateral isolation trench section having a first width and a narrow lateral isolation trench section having a second width, the first width being greater than the second width; forming contact via cavities such that a top surface of a respective one of the sacrificial material layers is exposed underneath each of the contact via cavities; performing a first isotropic etch process that isotropically recesses the sacrificial material layers employing the narrow lateral isolation trench sections as first conduits for a first isotropic etchant; performing a second isotropic etch process that isotropically recesses the sacrificial material layers employing the contact via cavities and employing at least one of the wide lateral isolation trench sections or access lateral isolation trenches as second conduits for a second isotropic etchant; and forming integrated word line and contact via structures in cavities that are formed by the first isotropic etch process and the second isotropic etch process, wherein each of the integrated word line and contact via structures comprises a respective horizontally-extending word line, a respective contact via structure, and a respective lateral connection strip connecting the respective horizontally-extending word line and the respective contact via structure.

### BRIEF DESCRIPTION OF THE DRAWINGS

FIG. 1 is a schematic vertical cross-sectional view of a first exemplary structure after formation of an alternating stack of insulating layers and sacrificial material layers over a substrate according to a first embodiment of the present disclosure.

FIG. 2A-2C are various views of the first exemplary structure after formation of memory openings according to the first embodiment of the present disclosure. FIG. 2C is a top-down view. FIG. 2A is a first vertical cross-sectional view along the vertical plane A-A′ in FIG. 2C. FIG. 2B is a second vertical cross-sectional view along the vertical plane B-B′ in FIG. 2C.

FIG. 3A-3F are sequential schematic vertical cross-sectional views of a memory opening within the first exemplary structure during formation of a memory opening fill structure therein according to the first embodiment of the present disclosure.

FIG. 4A-4C are various views of the first exemplary structure after formation of memory opening fill structures according to the first embodiment of the present disclosure. FIG. 4C is a top-down view. FIG. 4A is a first vertical cross-sectional view along the vertical plane A-A′ in FIG. 4C. FIG. 4B is a second vertical cross-sectional view along the vertical plane B-B′ in FIG. 4C.

FIG. 5A-5C are various views of the first exemplary structure after formation of dual-width lateral isolation trenches and access lateral isolation trenches according to the first embodiment of the present disclosure. FIG. 5C is a top-down view. FIG. 5A is a first vertical cross-sectional view along the vertical plane A-A′ in FIG. 5C. FIG. 5B is a second vertical cross-sectional view along the vertical plane B-B′ in FIG. 5C.

FIGS. 6A and 6B are vertical cross-sectional views of the first exemplary structure after formation of a sacrificial barrier liner and a sacrificial fill material layer according to the first embodiment of the present disclosure. FIG. 6A is a first vertical cross-sectional view along the vertical plane A-A′ in FIG. 5C. FIG. 6B is a second vertical cross-sectional view along the vertical plane B-B′ in FIG. 5C.

FIGS. 7A and 7B are vertical cross-sectional views of the first exemplary structure after isotropically recessing the sacrificial fill material layer and the sacrificial barrier liner according to the first embodiment of the present disclosure.

FIGS. 8A and 8B are vertical cross-sectional views of the first exemplary structure after formation of wide lateral isolation trench fill structures according to the first embodiment of the present disclosure.

FIG. 9A-9C are various views of the first exemplary structure after formation of contact via openings according to the first embodiment of the present disclosure. FIG. 9C is a top-down view. FIG. 9A is a first vertical cross-sectional view along the vertical plane A-A′ in FIG. 9C. FIG. 9B is a second vertical cross-sectional view along the vertical plane B-B′ in FIG. 9C.

FIGS. 10A and 10B are vertical cross-sectional views of the first exemplary structure after formation of tubular insulating spacers and vertical extension of contact via cavities according to the first embodiment of the present disclosure.

FIGS. 11A and 11B are vertical cross-sectional views of the first exemplary structure after removal of sacrificial isolation trench fill structures according to the first embodiment of the present disclosure.

FIGS. 12A and 12B are vertical cross-sectional views of the first exemplary structure after formation of a sacrificial barrier liner according to the first embodiment of the present disclosure.

FIGS. 13A and 13B are vertical cross-sectional views of the first exemplary structure after formation of a sacrificial dielectric liner according to the first embodiment of the present disclosure.

FIGS. 14A and 14B are vertical cross-sectional views of the first exemplary structure after patterning the sacrificial dielectric liner according to the first embodiment of the present disclosure.

FIGS. 15A and 15B are vertical cross-sectional views of the first exemplary structure after removal of a patterned photoresist layer according to the first embodiment of the present disclosure.

FIGS. 16A and 16B are vertical cross-sectional views of the first exemplary structure after removal of the sacrificial dielectric liner according to the first embodiment of the present disclosure.

FIG. 17A-17D are various views of the first exemplary structure after a first selective isotropic etch process that laterally recesses physically exposed portions of the sacrificial material layers by a first etch distance according to the first embodiment of the present disclosure. FIG. 17C is a top-down view. FIG. 17A is a first vertical cross-sectional view along the vertical plane A-A′ in FIG. 17C. FIG. 17B is a second vertical cross-sectional view along the vertical plane B-B′ in FIG. 17C. FIG. 17D is a horizontal cross-sectional view along the horizontal plane D-D′ of FIGS. 17A and 17B.

FIGS. 18A and 18B are vertical cross-sectional views of the first exemplary structure after removal of the sacrificial barrier liner according to the first embodiment of the present disclosure.

FIG. 19A-19E are various views of the first exemplary structure after a second selective isotropic etch process that laterally recesses physically exposed portions of the sacrificial material layers by a second etch distance according to the first embodiment of the present disclosure. FIG. 19C is a top-down view. FIG. 19A is a first vertical cross-sectional view along the vertical plane A-A′ in FIG. 19C. FIG. 19B is a second vertical cross-sectional view along the vertical plane B-B′ in FIG. 19C. FIG. 19D is a horizontal cross-sectional view along the horizontal plane D-D′ of FIGS. 19A and 19B. FIG. 19E is a horizontal cross-sectional view along the horizontal plane E-E′ of FIGS. 19A and 19B.

FIG. 20A-20E are various views of the first exemplary structure after formation of a continuous electrically conductive layer according to the first embodiment of the present disclosure. FIG. 20C is a top-down view. FIG. 20A is a first vertical cross-sectional view along the vertical plane A-A′ in FIG. 20C. FIG. 20B is a second vertical cross-sectional view along the vertical plane B-B′ in FIG. 20C. FIG. 20D is a horizontal cross-sectional view along the horizontal plane D-D′ of FIGS. 20A and 20B. FIG. 20E is a horizontal cross-sectional view along the horizontal plane E-E′ of FIGS. 20A and 20B.

FIG. 21A-21E are various views of the first exemplary structure after removing unmasked portions of the continuous electrically conductive layer according to the first embodiment of the present disclosure. FIG. 21C is a top-down view. FIG. 21A is a first vertical cross-sectional view along the vertical plane A-A′ in FIG. 21C. FIG. 21B is a second vertical cross-sectional view along the vertical plane B-B′ in FIG. 21C. FIG. 21D is a horizontal cross-sectional view along the horizontal plane D-D′ of FIGS. 21A and 21B. FIG. 21E is a horizontal cross-sectional view along the horizontal plane E-E′ of FIGS. 21A and 21B.

FIGS. 22A and 22B are vertical cross-sectional views of the first exemplary structure after formation of a continuous dielectric material portion including a contact-level dielectric layer and lateral isolation trench fill structures according to the first embodiment of the present disclosure.

FIG. 23A-23C are various views of the first exemplary structure after formation of drain contact via structures and connection via structures according to the first embodiment of the present disclosure. FIG. 23C is a top-down view. FIG. 23A is a first vertical cross-sectional view along the vertical plane A-A′ in FIG. 23C. FIG. 23B is a second vertical cross-sectional view along the vertical plane B-B′ in FIG. 23C.

FIG. 24A is a top-down view of an alternative configuration of the first exemplary structure according to the first embodiment of the present disclosure. FIG. 24B is a horizontal cross-sectional view of the alternative configuration of the first exemplary structure according to the first embodiment of the present disclosure.

FIG. 25A-25C are vertical cross-sectional views of a second exemplary structure after isotropically recessing the sacrificial fill material layer and the sacrificial barrier liner according to a second embodiment of the present disclosure. FIG. 25C is a top-down view. FIG. 25A is a first vertical cross-sectional view along the vertical plane A-A′ in FIG. 25C. FIG. 25B is a second vertical cross-sectional view along the vertical plane B-B′ in FIG. 25C.

FIG. 26 is a horizontal cross-sectional view of the second exemplary structure after conversion of surface portions of sacrificial narrow lateral isolation trench fill structures into dielectric liners according to the second embodiment of the present disclosure.

FIG. 27A-27C are vertical cross-sectional views of the second exemplary structure after formation of a first sacrificial trench liner, a second sacrificial trench liner, and wide sacrificial trench fill structures according to the second embodiment of the present disclosure. FIG. 27C is a top-down view. FIG. 27A is a first vertical cross-sectional view along the vertical plane A-A′ in FIG. 27C. FIG. 27B is a second vertical cross-sectional view along the vertical plane B-B′ in FIG. 27C.

FIG. 28A-28C are various views of the second exemplary structure after formation of contact via openings according to the second embodiment of the present disclosure. FIG. 28C is a top-down view. FIG. 28A is a first vertical cross-sectional view along the vertical plane A-A′ in FIG. 28C. FIG. 28B is a second vertical cross-sectional view along the vertical plane B-B′ in FIG. 28C.

FIGS. 29A and 29B are vertical cross-sectional views of the second exemplary structure after formation of tubular insulating spacers and vertical extension of contact via cavities according to the second embodiment of the present disclosure.

FIGS. 30A and 30B are vertical cross-sectional views of the second exemplary structure after formation of a sacrificial barrier liner and a sacrificial dielectric liner according to the second embodiment of the present disclosure.

FIGS. 31A and 31B are vertical cross-sectional views of the second exemplary structure after patterning the sacrificial dielectric liner according to the second embodiment of the present disclosure.

FIGS. 32A and 32B are vertical cross-sectional views of the second exemplary structure after removal of unmasked portions of the sacrificial barrier liner, narrow sacrificial lateral isolation trench fill structures, and wide sacrificial lateral isolation trench fill structures according to the second embodiment of the present disclosure.

FIGS. 33A and 33B are vertical cross-sectional views of the second exemplary structure after removal of a patterned photoresist layer, the sacrificial dielectric liner, and the second sacrificial trench liner according to the second embodiment of the present disclosure.

FIG. 34A-34D are various views of the second exemplary structure after a first selective isotropic etch process that laterally recesses physically exposed portions of the sacrificial material layers by a second etch distance according to the second embodiment of the present disclosure. FIG. 34C is a top-down view. FIG. 34A is a first vertical cross-sectional view along the vertical plane A-A′ in FIG. 34C. FIG. 34B is a second vertical cross-sectional view along the vertical plane B-B′ in FIG. 34C. FIG. 34D is a horizontal cross-sectional view along the horizontal plane D-D′ of FIGS. 34A and 34B.

FIGS. 35A and 35B are vertical cross-sectional views of the second exemplary structure after removal of the first sacrificial trench liner according to the second embodiment of the present disclosure.

FIG. 36A-36E are various views of the second exemplary structure after a second selective isotropic etch process that laterally recesses physically exposed portions of the sacrificial material layers by a second etch distance according to the second embodiment of the present disclosure. FIG. 36C is a top-down view. FIG. 36A is a first vertical cross-sectional view along the vertical plane A-A′ in FIG. 36C. FIG. 36B is a second vertical cross-sectional view along the vertical plane B-B′ in FIG. 36C. FIG. 36D is a horizontal cross-sectional view along the horizontal plane D-D′ of FIGS. 36A and 36B. FIG. 36E is a horizontal cross-sectional view along the horizontal plane E-E′ of FIGS. 36A and 36B.

FIG. 37A-37E are various views of the second exemplary structure after formation of integrated word line and contact via structures, a continuous dielectric material portion including a contact-level dielectric layer and lateral isolation trench fill structures, and drain contact via structures and connection via structures according to the second embodiment of the present disclosure. FIG. 37C is a top-down view. FIG. 37A is a first vertical cross-sectional view along the vertical plane A-A′ in FIG. 37C. FIG. 37B is a second vertical cross-sectional view along the vertical plane B-B′ in FIG. 37C. FIG. 37D is a horizontal cross-sectional view along the horizontal plane D-D′ of FIGS. 37A and 37B. FIG. 37E is a horizontal cross-sectional view along the horizontal plane E-E′ of FIGS. 37A and 37B.

FIG. 38A-38E are various views of a first alternative configuration of the second exemplary structure after formation of integrated word line and contact via structures, a continuous dielectric material portion including a contact-level dielectric layer and lateral isolation trench fill structures, and drain contact via structures and connection via structures according to the second embodiment of the present disclosure. FIG. 38C is a top-down view. FIG. 38A is a first vertical cross-sectional view along the vertical plane A-A′ in FIG. 38C. FIG. 38B is a second vertical cross-sectional view along the vertical plane B-B′ in FIG. 38C. FIG. 38D is a horizontal cross-sectional view along the horizontal plane D-D′ of FIGS. 38A and 38B. FIG. 38E is a horizontal cross-sectional view along the horizontal plane E-E′ of FIGS. 38A and 38B.

FIG. 39A-39E are various views of a second alternative configuration of the second exemplary structure after formation of integrated word line and contact via structures, a continuous dielectric material portion including a contact-level dielectric layer and lateral isolation trench fill structures, and drain contact via structures and connection via structures according to the second embodiment of the present disclosure. FIG. 39C is a top-down view. FIG. 39A is a first vertical cross-sectional view along the vertical plane A-A′ in FIG. 39C. FIG. 39B is a second vertical cross-sectional view along the vertical plane B-B′ in FIG. 39C. FIG. 39D is a horizontal cross-sectional view along the horizontal plane D-D′ of FIGS. 39A and 39B. FIG. 39E is a horizontal cross-sectional view along the horizontal plane E-E′ of FIGS. 39A and 39B.

FIGS. 40, 41, 42 and 43 are horizontal cross-sectional views of third, fourth, fifth and sixth alternative configurations of the second exemplary structure according to the second embodiment of the present disclosure.

### DETAILED DESCRIPTION

As discussed above, the embodiments of the present disclosure are directed to a three-dimensional memory device including integrated word line and via structures and methods for forming the same, the various aspects of which are described below. The embodiments of the present disclosure can be used to form various structures including a multilevel memory structure, non-limiting examples of which include semiconductor devices such as three-dimensional memory array devices comprising a plurality of NAND memory strings.

The drawings are not drawn to scale. Multiple instances of an element may be duplicated where a single instance of the element is illustrated, unless absence of duplication of elements is expressly described or clearly indicated otherwise. Ordinals such as “first,” “second,” and “third” are used merely to identify similar elements, and different ordinals may be used across the specification and the claims of the instant disclosure. The same reference numerals refer to the same element or similar element. Unless otherwise indicated, elements having the same reference numerals are presumed to have the same composition. Unless otherwise indicated, a “contact” between elements refers to a direct contact between elements that provides an edge or a surface shared by the elements. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, a “prototype” structure or an “in-process” structure refers to a transient structure that is subsequently modified in the shape or composition of at least one component therein. As used herein, a first electrical component is electrically connected to a second electrical component if there exists an electrically conductive path between the first electrical component and the second electrical component.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, or may have one or more layer thereupon, thereabove, and/or therebelow.

As used herein, a “semiconducting material” refers to a material having electrical conductivity in the range from 1.0×10⁻⁶ S/cm to 1.0×10⁵ S/cm. As used herein, a “semiconductor material” refers to a material having electrical conductivity in the range from 1.0×10⁻⁶ S/cm to 1.0×10⁵ S/cm in the absence of electrical dopants therein, and is capable of producing a doped material having electrical conductivity in a range from 1.0 S/cm to 1.0×10⁵ S/cm upon suitable doping with an electrical dopant. As used herein, an “electrical dopant” refers to a p-type dopant that adds a hole to a valence band within a band structure, or an n-type dopant that adds an electron to a conduction band within a band structure. As used herein, a “conductive material” refers to a material having electrical conductivity greater than 1.0×10⁵ S/cm. As used herein, an “insulator material” or a “dielectric material” refers to a material having electrical conductivity less than 1.0×10⁻⁶ S/cm. As used herein, a “heavily doped semiconductor material” refers to a semiconductor material that is doped with electrical dopant at a sufficiently high atomic concentration to become a conductive material either as formed as a crystalline material or if converted into a crystalline material through an anneal process (for example, from an initial amorphous state), i.e., to have electrical conductivity greater than 1.0×10⁵ S/cm. A “doped semiconductor material” may be a heavily doped semiconductor material, or may be a semiconductor material that includes electrical dopants (i.e., p-type dopants and/or n-type dopants) at a concentration that provides electrical conductivity in the range from 1.0×10⁻⁶ S/cm to 1.0×10⁵ S/cm. An “intrinsic semiconductor material” refers to a semiconductor material that is not doped with electrical dopants. Thus, a semiconductor material may be semiconducting or conductive, and may be an intrinsic semiconductor material or a doped semiconductor material. A doped semiconductor material can be semiconducting or conductive depending on the atomic concentration of electrical dopants therein. As used herein, a “metallic material” refers to a conductive material including at least one metallic element therein. All measurements for electrical conductivities are made at the standard condition.

Generally, a semiconductor package (or a “package”) refers to a unit semiconductor device that can be attached to a circuit board through a set of pins or solder balls. A semiconductor package may include a semiconductor chip (or a “chip”) or a plurality of semiconductor chips that are bonded thereamongst, for example, by flip-chip bonding or another chip-to-chip bonding. A package or a chip may include a single semiconductor die (or a “die”) or a plurality of semiconductor dies. A die is the smallest unit that can independently execute external commands or report status. Typically, a package or a chip with multiple dies is capable of simultaneously executing as many external commands as the total number of dies therein. Each die includes one or more planes. Identical concurrent operations can be executed in each plane within a same die, although there may be some restrictions. In case a die is a memory die, i.e., a die including memory elements, concurrent read operations, concurrent write operations, or concurrent erase operations can be performed in each plane within a same memory die. Each plane contains a number of memory blocks (or “blocks”), which are the smallest unit that can be erased by in a single erase operation. Each memory block contains a number of pages, which are the smallest units that can be selected for programming.

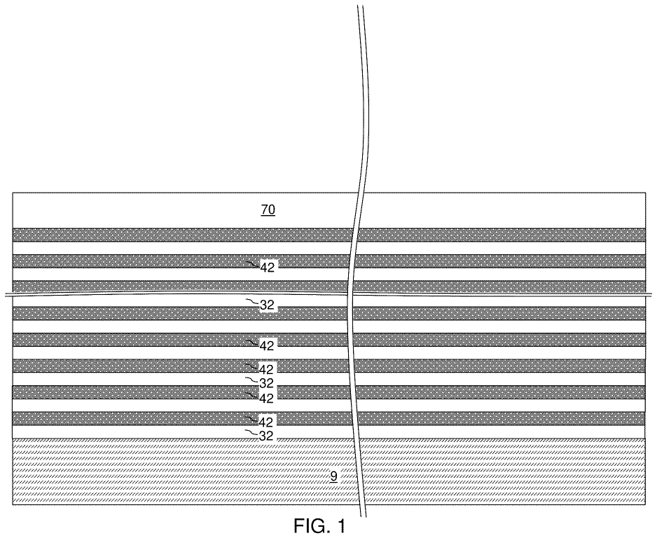

Referring to FIG. 1, a first exemplary structure according to the first embodiment of the present disclosure is illustrated, which can be used, for example, to fabricate a device structure containing vertical NAND memory devices. The first exemplary structure includes a substrate including a semiconductor material layer at least at an upper portion thereof. The semiconductor material layer 9 includes at least one elemental semiconductor material (e.g., a doped well in a single crystal silicon wafer or a deposited silicon layer), at least one III-V compound semiconductor material, at least one II-VI compound semiconductor material, at least one organic semiconductor material, or other semiconductor materials known in the art. In one embodiment, the semiconductor material layer may comprise a semiconductor material having a doping of a first conductivity type.

A stack of an alternating plurality of insulating layers 32 and sacrificial material layers 42 can be formed over the semiconductor material layer 9. The stack of the alternating plurality is herein referred to as an alternating stack (32, 42). In one embodiment, the alternating stack (32, 42) can include insulating layers 32 composed of the first material, and sacrificial material layers 42 composed of a second material different from that of insulating layers 32. The first material of the insulating layers 32 can be at least one insulating material. As such, each insulating layer 32 can be an insulating material layer. Insulating materials that can be used for the insulating layers 32 include, but are not limited to, silicon oxide (including doped or undoped silicate glass), silicon nitride, silicon oxynitride, organosilicate glass (OSG), spin-on dielectric materials, dielectric metal oxides that are commonly known as high dielectric constant (high-k) dielectric oxides (e.g., aluminum oxide, hafnium oxide, etc.) and silicates thereof, dielectric metal oxynitrides and silicates thereof, and organic insulating materials. In one embodiment, the first material of the insulating layers 32 can be silicon oxide.

The second material of the sacrificial material layers 42 is a sacrificial material that can be removed selective to the first material of the insulating layers 32. As used herein, a removal of a first material is “selective to” a second material if the removal process removes the first material at a rate that is at least twice the rate of removal of the second material. The ratio of the rate of removal of the first material to the rate of removal of the second material is herein referred to as a “selectivity” of the removal process for the first material with respect to the second material.

The sacrificial material layers 42 may comprise a dielectric material. In one embodiment, the sacrificial material layers 42 may comprise, and/or may consist essentially of, silicon nitride. The insulating layers 32 can be deposited, for example, by chemical vapor deposition (CVD). For example, if silicon oxide is used for the insulating layers 32, tetraethyl orthosilicate (TEOS) can be used as the precursor material for the CVD process. The sacrificial material layers 42 can be formed, for example, CVD or atomic layer deposition (ALD).

The thicknesses of the insulating layers 32 and the sacrificial material layers 42 can be in a range from 20 nm to 50 nm, although lesser and greater thicknesses can be used for each insulating layer 32 and for each sacrificial material layer 42. The number of repetitions of the pairs of an insulating layer 32 and a sacrificial material layer (e.g., a control gate electrode or a sacrificial material layer) 42 can be in a range from 2 to 1,024, and typically from 8 to 256, although a greater number of repetitions can also be used. The top and bottom gate electrodes in the stack may function as the select gate electrodes. In one embodiment, each sacrificial material layer 42 in the alternating stack (32, 42) can have a uniform thickness that is substantially invariant within each respective sacrificial material layer 42.

Optionally, an insulating cap layer 70 can be formed over the alternating stack (32, 42). The insulating cap layer 70 includes a dielectric material that is different from the material of the sacrificial material layers 42. In one embodiment, the insulating cap layer 70 can include a dielectric material that can be used for the insulating layers 32 as described above. The insulating cap layer 70 can have a greater thickness than each of the insulating layers 32. The insulating cap layer 70 can be deposited, for example, by chemical vapor deposition. In one embodiment, the insulating cap layer 70 can be a silicon oxide layer.

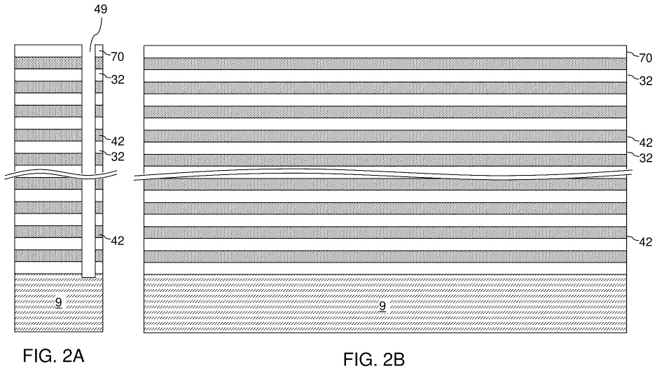

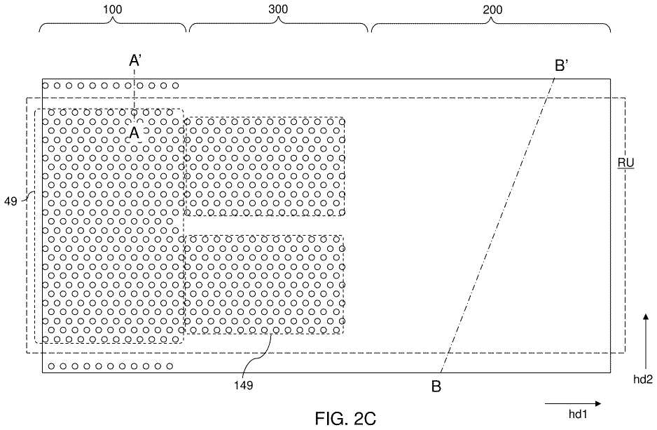

Referring to FIG. 2A-2C, a lithographic material stack (not shown) including at least a photoresist layer can be formed over the insulating cap layer 70, and can be lithographically patterned to form openings therein. The pattern in the lithographic material stack can be transferred through the insulating cap layer 70 and through the alternating stack (32, 42) by at least one anisotropic etch that uses the patterned lithographic material stack as an etch mask. Memory openings 49 are formed in a memory array region 100. As used herein, a “memory opening” refers to a structure in which memory elements, such as a memory stack structure, is subsequently formed. In one embodiment, the memory openings 49 may have a horizontal cross-sectional shape of a circle. In one embodiment, no openings are formed in a contact region 200, which is laterally spaced from the memory array region 100, and is subsequently employed to form contact via structures. The contact region 200 may be laterally spaced from the memory array region 100 along a first horizontal direction (e.g., word line direction) hd1. Dummy memory openings 149 can be formed in a connection region 300, which may be located between the memory array region 100 and the contact region 200.

In one embodiment, the pattern of the memory openings 49 and the dummy memory openings 149 may be a periodic pattern that is repeated along a second horizontal direction (e.g., bit line direction) hd2 that is perpendicular to the first horizontal direction hd1. The unit of repetition for the pattern of the memory openings 49 and the dummy memory openings 149 is herein referred to as a repetition unit RU. Each repetition unit RU may correspond to a memory block or to a portion of a memory block. Each repetition unit RU may comprise a two-dimensional array of memory openings 49 in the memory array region 100. The two-dimensional array of memory openings 49 may comprise a plurality of rows of memory openings 49, and each row of memory openings 49 may be arranged along the first horizontal direction hd2. Each repetition unit RU may comprise at least one two-dimensional array of dummy memory openings 149 in the connection region 300. In one embodiment, the number of rows of the memory openings 49 may be greater than the number of rows of dummy memory openings 149. In one embodiment, a width along the second horizontal direction hd2 of an area occupied by the memory openings 49 may be greater than the width along the second horizontal direction hd2 of an area occupied by the dummy memory openings 149.

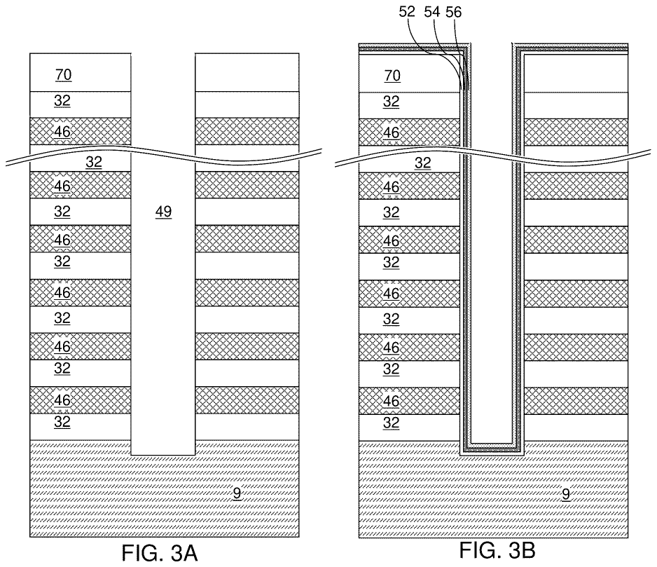

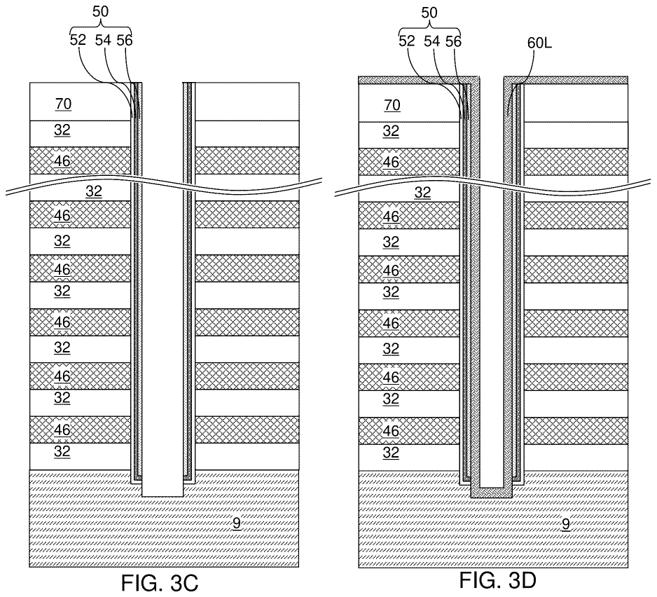

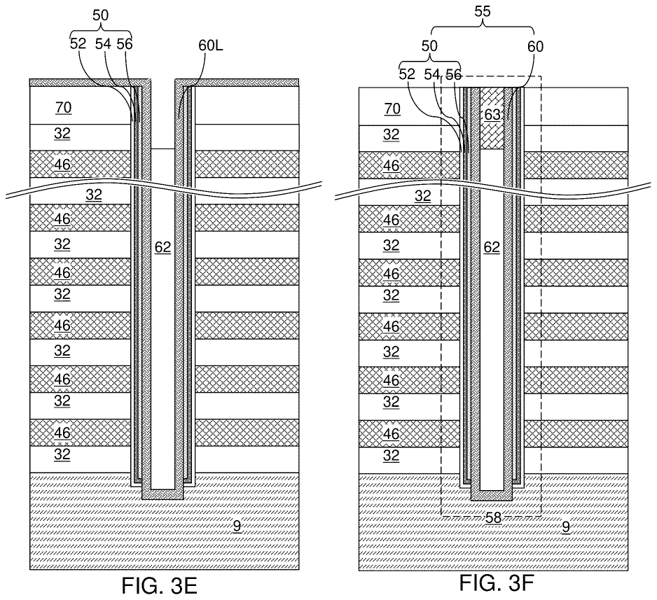

FIG. 3A-3F are sequential schematic vertical cross-sectional views of a memory opening 49 within the first exemplary structure during formation of a memory opening fill structure 58 therein according to the first embodiment of the present disclosure.

Referring to FIG. 3A, a memory opening 49 is illustrated after the processing steps described with reference to FIG. 2A-2C.

Referring to FIG. 3B, a set of material layers can be conformally deposited, which may include an optional blocking dielectric layer 52, a memory material layer 54, and an optional dielectric liner 56. The blocking dielectric layer 52 may comprise at least one blocking dielectric material such as silicon oxide and/or a dielectric metal oxide. The memory material layer 54 may comprise any memory material that can store memory bits therein. For example, the memory material layer 54 may comprise a charge storage layer, such as a silicon nitride layer. Alternatively, the memory material layer 54 may comprise a ferroelectric memory material, a resistive memory material, a phase change memory material, or any other memory material known in the art. In some embodiments, the memory material layer 54 may comprise a vertical stack of discrete memory material portions that are formed at levels of the electrically conductive layers 46. Generally, the memory material layer 54 may comprise a vertical stack of memory elements that are formed at the levels of the electrically conductive layers 46. In one embodiment, the vertical stack of memory elements comprises portions of the memory material layer 54 located at the levels of the electrically conductive layers 46. The optional dielectric liner 56, if present, can provide electrical isolation between the memory material layer 54 and a semiconductor channel to be subsequently formed. In case the memory material layer 54 comprises a charge storage material, the optional dielectric liner 56 may comprise a tunneling dielectric layer.

Referring to FIG. 3C, an anisotropic etch process may be performed to remove horizontally-extending portions of the optional blocking dielectric layer 52, the memory material layer 54, and the optional dielectric liner 56. The combination of vertically-extending portions of the optional blocking dielectric layer 52, the memory material layer 54, and the optional dielectric liner 56 that remain in a respective memory opening 49 constitutes a memory film 50.

Referring to FIG. 3D, a semiconductor channel layer 60L can be deposited over the memory films 50. The semiconductor channel layer 60L includes a semiconductor material such as at least one elemental semiconductor material, at least one III-V compound semiconductor material, at least one II-VI compound semiconductor material, at least one organic semiconductor material, or other semiconductor materials known in the art. In one embodiment, the semiconductor channel layer 60L includes amorphous silicon or polysilicon. The semiconductor channel layer 60L can be formed by a conformal deposition method such as low pressure chemical vapor deposition (LPCVD). In one embodiment, the semiconductor channel layer 60L can be deposited as an amorphous semiconductor material. The thickness of the semiconductor channel layer 60L can be in a range from 2 nm to 10 nm, although lesser and greater thicknesses can also be used. A memory cavity is formed in the volume of each memory opening 49 that is not filled with the deposited material layers (52, 54, 56, 60L).

Referring to FIG. 3E, a dielectric core layer can be deposited to fill any remaining portion of the memory cavity within each memory opening. The dielectric core layer includes a dielectric material, such as silicon oxide or organosilicate glass. The dielectric core layer can be deposited by a conformal deposition method such as low pressure chemical vapor deposition (LPCVD), or by a self-planarizing deposition process such as spin coating. The dielectric core layer can be subsequently recessed selective to the material of the semiconductor channel layer 60L, for example, by a recess etch. The material of the dielectric core layer is vertically recessed below the horizontal plane including the top surface of the insulating cap layer 70. Each remaining portion of the dielectric core layer constitutes a dielectric core 62.

Referring to FIG. 3F, a doped semiconductor material having a doping of a second conductivity type can be deposited within each recess cavity located above the dielectric cores 62. The second conductivity type is the opposite of the first conductivity type. For example, if the first conductivity type is p-type, the second conductivity type is n-type, and vice versa. In one embodiment, the doped semiconductor material may be deposited as an amorphous semiconductor material. The dopant concentration in the doped semiconductor material having a doping of the second conductivity type can be in a range from 5.0×10¹⁸/cm³ to 2.0×10²¹/cm³, although lesser and greater dopant concentrations can also be used.

A planarization process can be performed to remove portions of the doped semiconductor material having a doping of the second conductivity type and the semiconductor channel layer 60L from above the top surface of the insulating cap layer 70, for example, by chemical mechanical planarization (CMP) or a recess etch to form drain regions 63. Each remaining portion of the semiconductor material having a doping of the second conductivity type constitutes a drain region 63. Each remaining portion of the semiconductor channel layer 60L constitutes a vertical semiconductor channel 60. Electrical current can flow through each vertical semiconductor channel 60 when a vertical NAND device including the vertical semiconductor channel 60 is turned on. Within each memory opening 49, a dielectric liner 56 is surrounded by a memory material layer 54, and laterally surrounds a vertical semiconductor channel 60. Each adjoining set of a blocking dielectric layer 52, a memory material layer 54, and a dielectric liner 56 collectively constitute a memory film 50, which can store electrical charges with a macroscopic retention time. In some embodiments, a blocking dielectric layer 52 may not be present in the memory film 50 at this step, and a blocking dielectric layer may be subsequently formed after formation of laterally-extending cavities. As used herein, a macroscopic retention time refers to a retention time suitable for operation of a memory device as a permanent memory device such as a retention time in excess of 24 hours. Each combination of a memory film 50 and a vertical semiconductor channel 60 constitutes a memory stack structure 55.

Each contiguous combination of a vertical semiconductor channel 60 and a memory film 50 constitutes a memory stack structure 55. Thus, each memory stack structure 55 can include a vertical semiconductor channel 60, a dielectric liner 56, a plurality of memory elements comprising portions of the memory material layer 54, and an optional blocking dielectric layer 52. Each combination of a memory stack structure 55, a dielectric core 62, and a drain region 63 within a memory opening 49 is herein referred to as a memory opening fill structure 58.

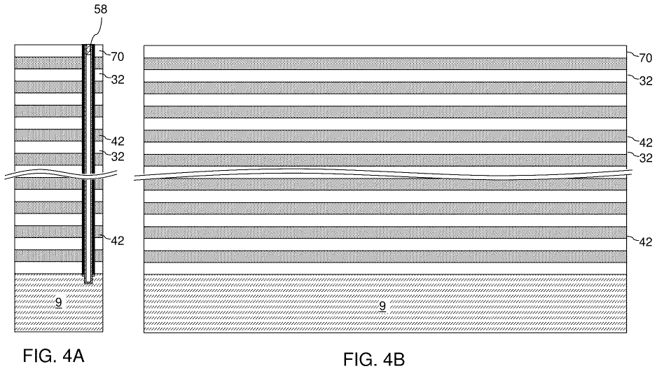

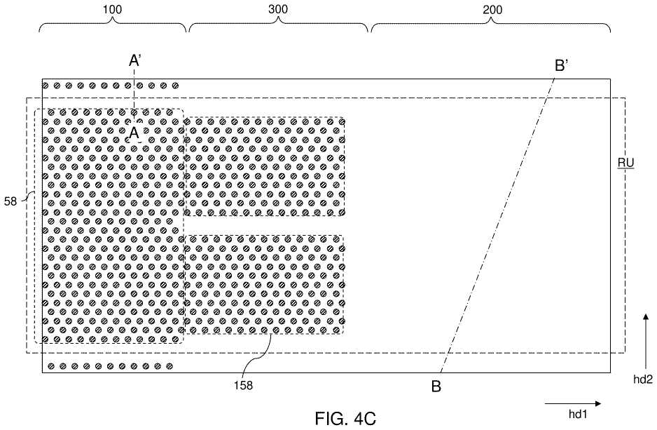

Referring to FIG. 4A-4C, the first exemplary structure is illustrated after the processing steps described with reference to FIG. 3F. Memory opening fill structures 58 are formed in the memory openings 49 in the memory array region 100. Generally, an alternating stack of insulating layers 32 and sacrificial material layers 42 is formed over a substrate, and memory openings 49 are formed through the alternating stack (32, 42). Memory opening fill structures 58 are formed in the memory openings 49. Each of the memory opening fill structures 58 comprises a respective vertical stack of memory elements (which may comprise portions of the respective memory material layer 54), a vertical semiconductor channel 60 and a drain region 63. Dummy memory opening fill structures 158 are formed in the dummy memory openings 149 in the connection region 300. Dummy memory opening fill structures 158 may have the same composition as the memory opening fill structures 58, except that the dummy drain regions of the dummy memory opening fill structures 158 are not electrically connected to subsequently formed bit lines, and therefore the dummy memory opening fill structures 158 do not store data during operation of the memory device. In one embodiment, the number of rows of the memory opening fill structures 58 may be greater than the number of rows of dummy memory opening fill structures 158. In one embodiment, a width along the second horizontal direction hd2 of an area occupied by the memory opening fill structures 58 may be greater than the width along the second horizontal direction hd2 of an area occupied by the dummy memory opening fill structures 158.

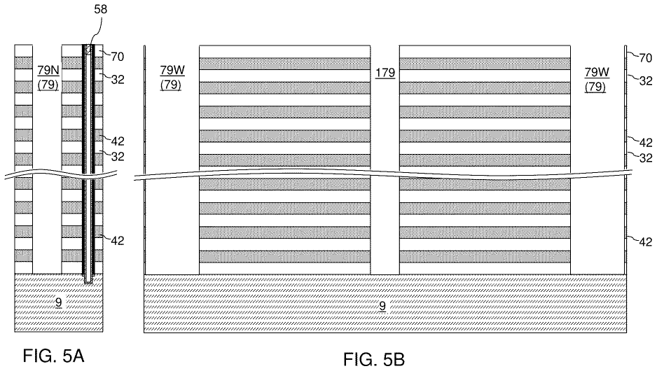

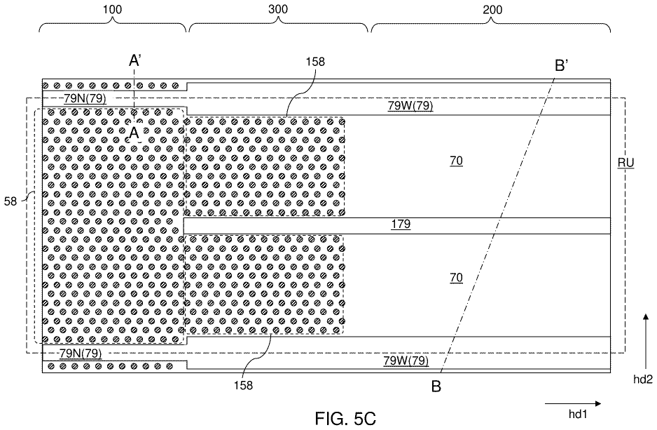

Referring to FIG. 5A-5C, a photoresist layer (not shown) can be applied over the insulating cap layer 70, and can be lithographically patterned to form elongated openings that laterally extend along the first horizontal direction hd1. An anisotropic etch process is performed to etch through unmasked portions of the insulating cap layer 70 and the alternating stack (32, 42) to form various trenches, which are herein referred to as lateral isolation trenches (79, 179). The photoresist layer can be subsequently removed, for example, by ashing.

According to an aspect of the present disclosure, the lateral isolation trenches (79, 179) include dual-width lateral isolation trenches 79 and access lateral isolation trenches 179 that are interlaced along the second horizontal direction hd2 with a uniform pitch along the second horizontal direction hd2. The uniform pitch may be the same as the width of each repetition unit RU (e.g., memory block width) along the second horizontal direction (e.g., bit line direction) hd2. Each dual-width lateral isolation trench 79 comprises a respective wide lateral isolation trench section 79W having a first width and a narrow lateral isolation trench section 79N having a second width. The first width is greater than the second width. In one embodiment, the second width is greater than the thickness of each sacrificial material layer 42. In one embodiment, the second width may be greater than the thickness of each sacrificial material layer 42 at least by a factor of 2, and preferably by a factor of 4, and more preferably by a factor of 10. The first width is greater than the second width at least by the thickness of each sacrificial material layer 42, and preferably by twice, and/or four times, and/or 8 times, the thickness of each sacrificial material layer 42. Each access lateral isolation trench 179 may have a uniform width that is the same as or about the same as the second width.

In one embodiment, each wide lateral isolation trench section 79W and each access lateral isolation trench 179 laterally extend through the contact region 200 and the connection region 300, and do not extend into the memory array region 100. Each narrow lateral isolation trench section 79N laterally extends through the memory array region 100. Each narrow lateral isolation trench section 79N may be adjoined to a respective wide lateral isolation trench section 79W at or adjacent to a boundary between the memory array region 100 and the connection region 300. Generally, the dual-width lateral isolation trenches 79 and the access lateral isolation trenches 179 may be formed simultaneously employing an anisotropic etch process. The dual-width lateral isolation trenches 79 and the access lateral isolation trenches 179 laterally extend along the first horizontal direction hd1, and are interlaced along the second horizontal direction hd2 such that the dual-width lateral isolation trenches 79 and the access lateral isolation trenches 179 alternate along the second horizontal direction Hd2.

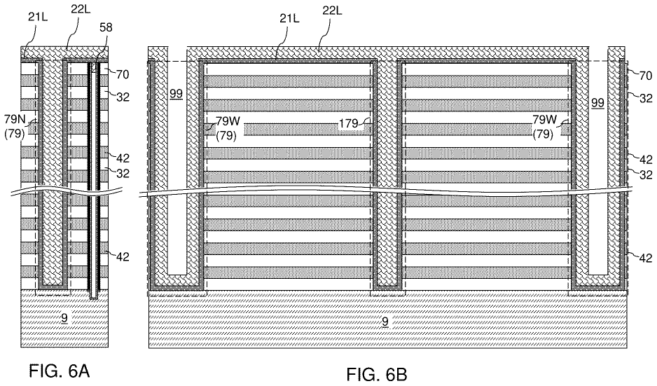

Referring to FIGS. 6A and 6B, a sacrificial barrier liner 21L may be conformally deposited on the first exemplary structure. The sacrificial barrier liner 21L may comprise a dielectric material, such as silicon nitride, and may have a thickness in a range from 5 nm to 30 nm, although lesser or greater thicknesses may also be employed.

A sacrificial fill material layer 22L can be conformally deposited over the sacrificial barrier liner 21L. The sacrificial fill material layer 22L comprises a sacrificial fill material that may be subsequently removed selectively to the material of the sacrificial barrier liner 21L. For example, the sacrificial fill material layer 22L may comprise amorphous silicon or polysilicon. The thickness of the sacrificial fill material layer 22L can be selected such that the sacrificial fill material layer 22L fills the volumes of the cavities in the narrow lateral isolation trench sections 79N and the access lateral isolation trenches 179 without completely filing the volumes of the cavities in the wide lateral isolation trench sections 79W. Thus, elongated wall-shaped voids 99 are present within the volumes of the wide lateral isolation trench sections 79W.

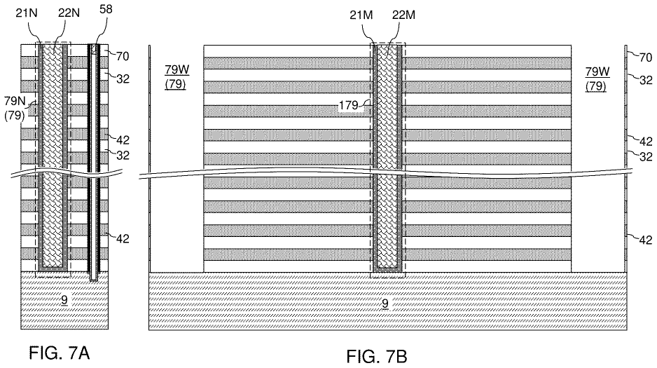

Referring to FIGS. 7A and 7B, a first isotropic etch process can be performed to isotropically etch back physically exposed portions of the sacrificial fill material layer 22L. The duration of the first isotropic etch back process can be selected such that the material of the sacrificial fill material layer 22L is completely removed from inside the wide lateral isolation trench sections 79W, while portions of the sacrificial fill material layer 22L located within the narrow lateral isolation trench sections 79N and the access lateral isolation trenches 179 are not removed. Each remaining portion of the sacrificial fill material layer 22L that remains in a narrow lateral isolation trench section 79N is herein referred to as a sacrificial narrow isolation trench fill structure 22N. Each remaining portion of the sacrificial fill material layer 22L that remains in an access lateral isolation trench 179 is herein referred to as a sacrificial access lateral isolation trench fill structure 22M.

A second isotropic etch process can be performed to isotropically etch back physically exposed portions of the sacrificial barrier liner 21L. The duration of the second isotropic etch back process can be selected such that the material of the sacrificial barrier liner 21L is completely removed from inside the wide lateral isolation trench sections 79W, while the covered portions of the sacrificial barrier liner 21L located within the narrow lateral isolation trench sections 79N and the access lateral isolation trenches 179 are not removed. Each remaining portion of the sacrificial barrier liner 21L that remains in a narrow lateral isolation trench section 79N is herein referred to as a sacrificial narrow trench liner 21N. Each remaining portion of the sacrificial barrier liner 21L that remains in an access lateral isolation trench 179 is herein referred to as a sacrificial access lateral isolation trench liner 21M.

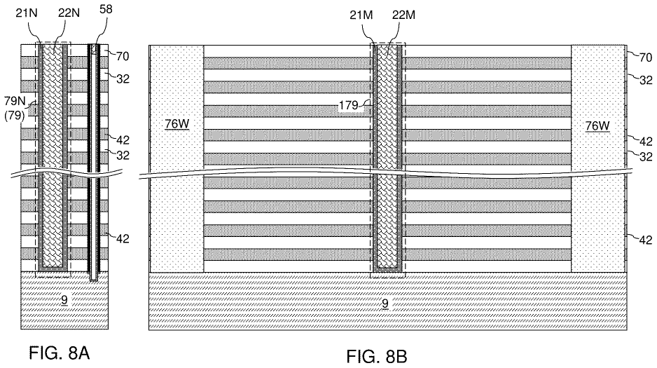

Referring to FIGS. 8A and 8B, a first dielectric fill material, such as undoped silicate glass (i.e., silicon oxide) or a doped silicate glass can be deposited in the volumes of the voids in the wide lateral isolation trench sections 79W. A planarization process, such as a chemical mechanical polishing process, can be performed to remove portions of the first dielectric fill material from above the horizontal plane including the top surface of the insulating cap layer 70. Each remaining portion of the first dielectric fill material that fills a respective wide lateral isolation trench section 79W constitutes a wide lateral isolation trench fill structure 76W. Top surfaces of the lateral isolation trench fill structure 76W may be formed within the horizontal plane including the top surface of the insulating cap layer 70. Each wide lateral isolation trench fill structure 76W may have a uniform width along the second horizontal direction hd2, which may be the first width.

Generally, neighboring pairs of alternating stacks (32, 42) of insulating layers 32 and sacrificial material layers 42 may be laterally spaced apart from each other by a respective dual-width lateral isolation trench 79 having a wide lateral isolation trench section 79W and a narrow lateral isolation trench section 79N. The wide lateral isolation trench section 79W is filled with a wide lateral isolation trench fill structure 76W that comprises the first dielectric fill material.

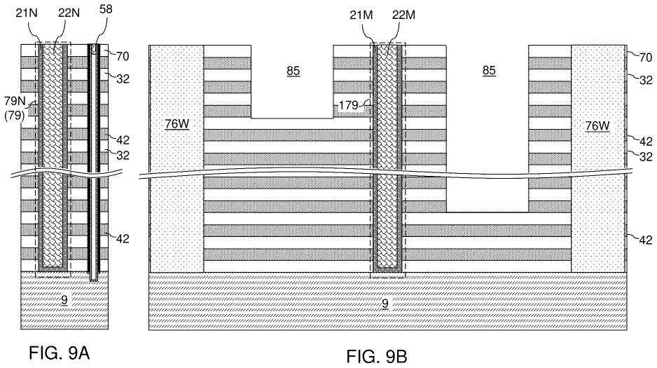

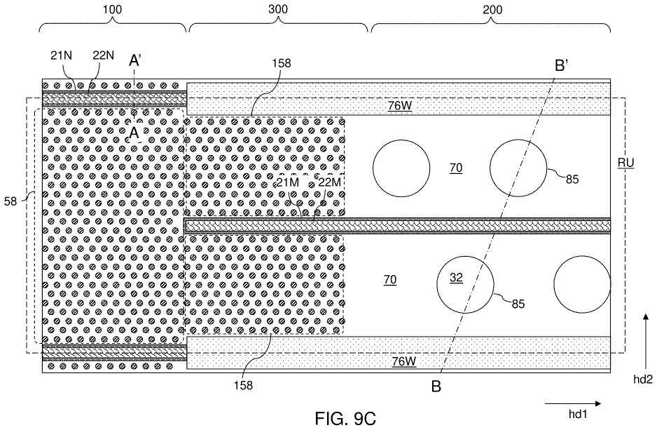

Referring to FIG. 9A-9C, contact via openings 85 are formed within the contact region 200. Each of the contact via openings 85 can vertically extend through the insulating cap layer 70 and optionally through a respective subset of the sacrificial material layers 42 and the insulating layers 32 such that a top surface of an insulating layer 32 is physically exposed at the bottom of each contact via opening 85. In one embodiment, the contact via openings 85 may have different depths from each other. In one embodiment, a contact via opening 85 may be provided for each insulating layer 32 such that a top surface segment of the insulating layer 32 is physically exposed underneath a respective one of the contact via openings 85.

The contact via openings 85 having different depths may be formed employing a plurality of masked anisotropic etch processes. In an illustrative example, a patterned hard mask layer (not shown) including openings therethrough may be formed over the insulating cap layer 70. The patterned hard mask layer may comprise a dielectric material such as silicon nitride, and/or a metallic material such as TiN. The openings in the patterned hard mask layer may have the pattern of all of the contact via openings 85 to be subsequently formed. An anisotropic etch process may be performed to transfer the pattern of the openings in the patterned hard mask layer through the insulating cap layer 70.

Subsequently, multiple iterations of a combination of a respective masking process and a respective anisotropic etch process may be performed to etch through a respective subset of the sacrificial material layers 42 and the insulating layers 32. Each masking process forms a respective patterned photoresist layer that masks a respective subset of the openings in the patterned hard mask layer without masking a respective complementary subset of the openings. Each anisotropic etch process etches a respective number of sacrificial material layers 42 and a respective number of insulating layers 32 underneath each opening in the pattered hard mask layer that is not masked by a respective patterned photoresist layer. In one embodiment, the number of etched sacrificial material layers 42 and etched insulating layers 32 underneath unmasked openings in the patterned hard mask layer may be a non-negative integer power of 2, i.e., 1, 2, 4, 8, 16, 32, 64, etc. By employing a combination of various masking patterns for the patterned photoresist layers, the total depths of the contact via openings 85 can be varied to enable physical exposure of the top surfaces of sacrificial material layers 42 at each level of the electrically conductive layers 46. The patterned hard mask layer can be subsequently removed. The lateral dimensions (such as diameters) of the contact via openings 85 may be in a range from 30 nm to 300 nm, although lesser and greater lateral dimensions may also be employed. Generally, a contact via opening 85 may vertically extend through an alternating stack of insulating layers 32 and sacrificial material layers 42.

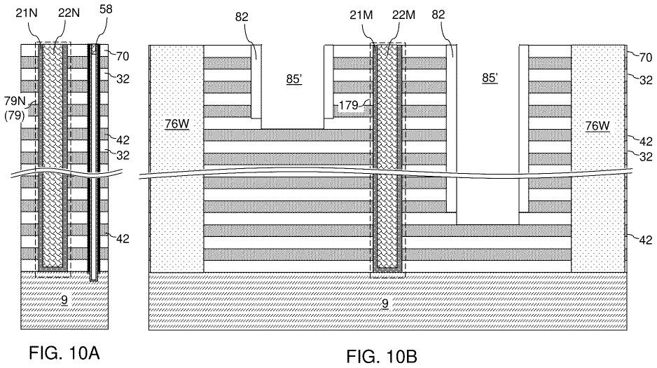

Referring to FIGS. 10A and 10B, tubular insulating spacers 82 may be formed in peripheral regions of the contact via openings 85 by depositing a conformal insulating material layer, such as a silicon oxide layer, and by performing an anisotropic etch process that etches horizontally-extending portions of the conformal insulating material layer. Remaining tubular portions of the conformal insulating material layer constitute the tubular insulating spacers 82. The anisotropic etch process can be prolonged to etch through unmasked portions of the insulating layers 32 such that contact via cavities 85′ laterally surrounded by the tubular insulating spacers 82 are vertically extended. A top surface segment of a respective underlying sacrificial material layer 42 may be physically exposed underneath each contact via cavity 85′.

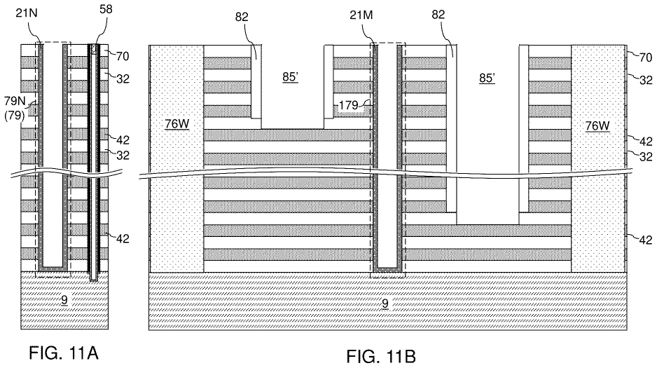

Referring to FIGS. 11A and 11B, a selective etch process can be performed to remove sacrificial narrow lateral isolation trench fill structures 22N and sacrificial access lateral isolation trench fill structures 22M. Voids are formed in the volumes from which the sacrificial narrow lateral isolation trench fill structures 22N and the sacrificial access lateral isolation trench fill structures 22M are removed.

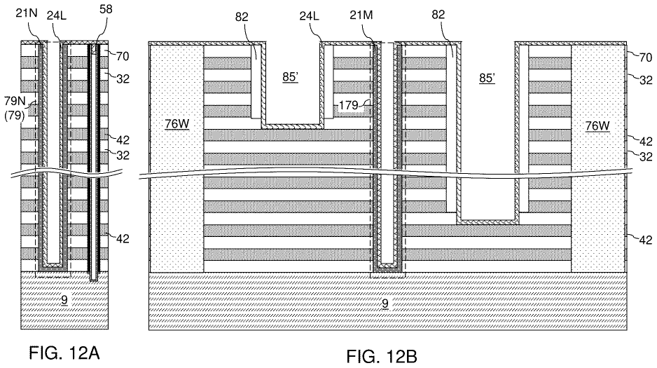

Referring to FIGS. 12A and 12B, a sacrificial barrier liner 24L can be deposited in the voids and over the insulating cap layer 70 by performing a first conformal deposition process. The sacrificial barrier liner 24L comprises a sacrificial barrier material that may be subsequently removed selectively to the material of the sacrificial narrow trench liners 21N and the sacrificial access lateral isolation trench liners 21M. For example, the sacrificial barrier liner 24L may comprise amorphous silicon or polysilicon having thickness in a range from 30 nm to 100 nm, although lesser or greater thicknesses may also be employed.

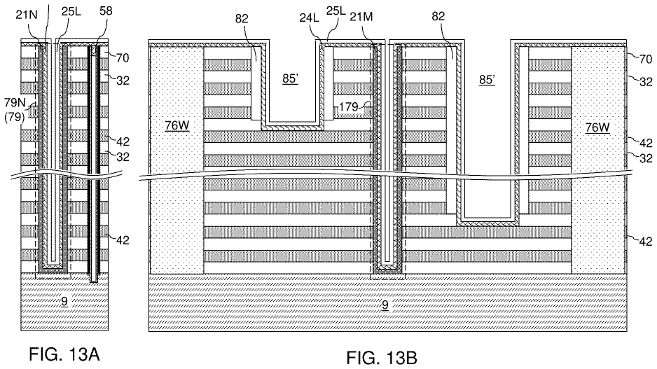

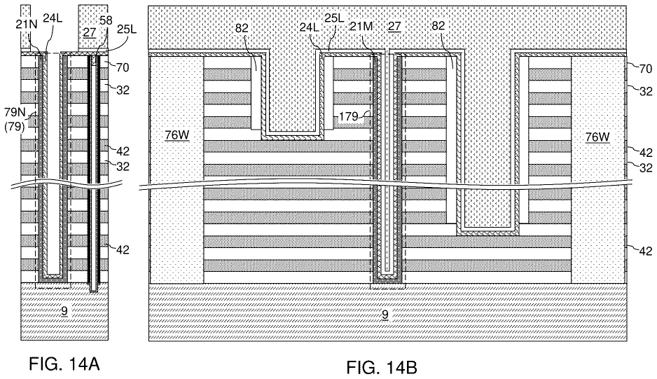

Referring to FIGS. 13A and 13B, a sacrificial dielectric liner 25L can be deposited by performing a second conformal deposition process. The sacrificial dielectric liner 25L comprises a sacrificial dielectric material that may be subsequently removed selectively to the material of the sacrificial barrier liner 24L. For example, the sacrificial dielectric liner 25L may comprise silicon oxide having thickness in a range from 5 nm to 30 nm, although lesser or greater thicknesses may also be employed.

Referring to FIGS. 14A and 14B, a photoresist layer 27 can be applied over the first exemplary structure, and can be lithographically patterned to form openings over the areas of the narrow lateral isolation trench sections 79N while covering areas outside of the narrow lateral isolation trench sections 79N in a plan view. A first etch process can be performed to remove unmasked portions of the sacrificial dielectric liner 25L selectively to the material of the sacrificial barrier liner 24L. Each portion of the sacrificial dielectric liner 25L located within the narrow lateral isolation trench sections 79N may be removed, and surfaces of the sacrificial barrier liner 24L may be physically exposed around the wall-shaped cavities within the volumes of the narrow lateral isolation trench sections 79N.

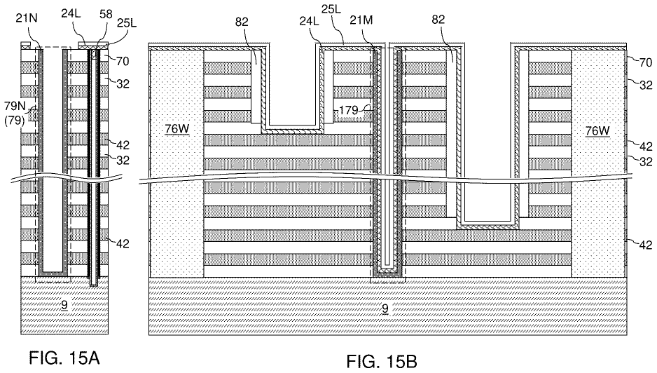

Referring to FIGS. 15A and 15B, a second etch process can be performed to remove unmasked portions of the sacrificial barrier liner 24L selectively to the materials of the sacrificial dielectric liner 25L and the sacrificial narrow trench liners 21N. Surfaces of the sacrificial narrow trench liners 21N are physically exposed in the narrow lateral isolation trench sections 79N. The photoresist layer 27 can be subsequently removed, for example, by ashing.

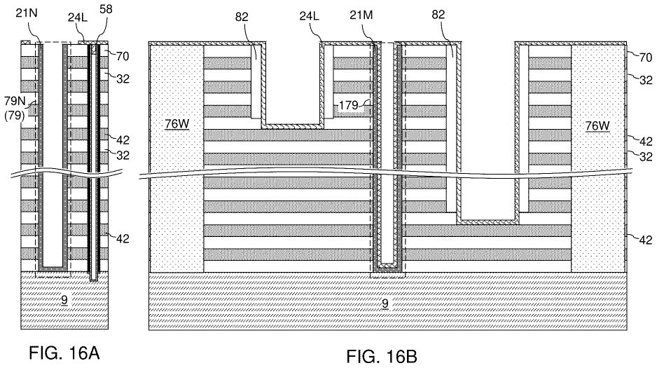

Referring to FIGS. 16A and 16B, remaining portions of the sacrificial dielectric liner 25L can be removed selectively to the material of the sacrificial barrier liner 24L. For example, if the sacrificial dielectric liner 25L comprises silicon oxide, a wet etch process employing dilute hydrofluoric acid may be performed to remove the sacrificial dielectric liner 25L.

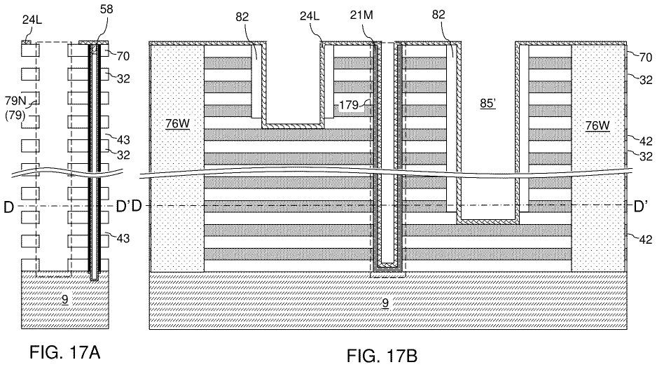

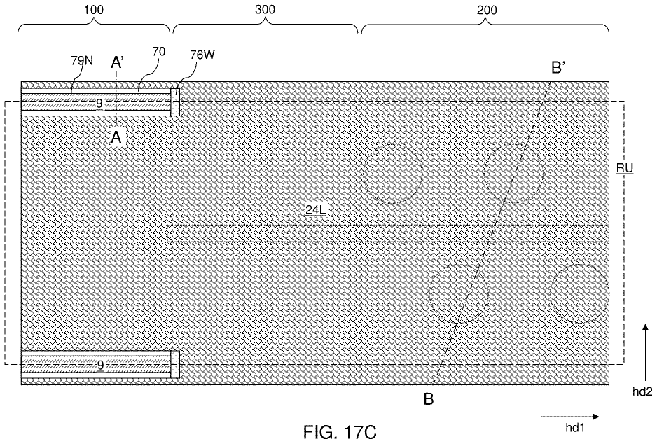

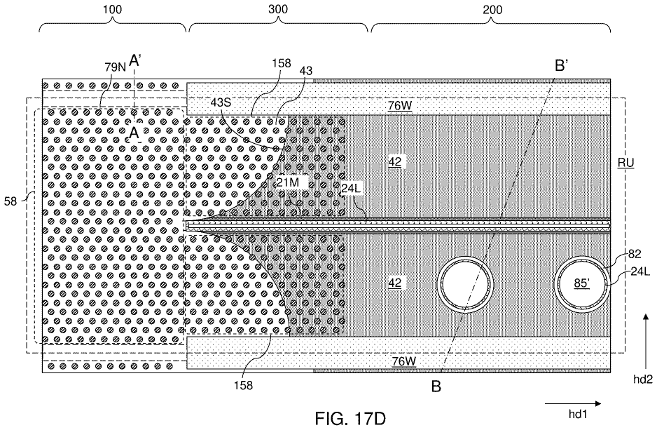

Referring to FIG. 17A-17D, a first selective isotropic etch process can be performed, which etches the materials of the sacrificial narrow trench liners 21N and the sacrificial material layers 42. In one embodiment, the sacrificial narrower trench liners 21N, the sacrificial access lateral isolation trench liners 21M, and the sacrificial material layers 42 may comprise the same material, such as silicon nitride. The first selective isotropic etch process removes the entirety of the sacrificial narrow trench liners 21N and laterally recesses physically exposed portions of the sacrificial material layers 42 by a first etch distance, but does not etch the sacrificial access lateral isolation trench liners 21M that are covered by the sacrificial barrier liner 24L.

Generally, the sacrificial material layers 42 are isotropically recessed from around the narrow lateral isolation trench sections 79N by the first lateral etch distance selectively to the materials of the insulating layers 32, the insulating cap layer 70, the tubular insulating spacers 82, the semiconductor material layer 9, and the material of the outermost layers of the memory films 50. Laterally-extending cavities 43 are formed in volumes from which the sacrificial material layers 42 are removed. The first lateral etch distance is greater than the lateral spacing between neighboring pairs of narrow lateral isolation trench sections 79N. Thus, a continuous void that laterally extends through all of the repetition units RU can be formed in the memory array region 100 at each level of the sacrificial material layers 42.

The first selective isotropic etch process may comprise a wet etch process employing a wet etch solution, and/or may comprise a gas phase (dry) etch process in which the etchant is introduced in a vapor phase into the narrow lateral isolation trench sections 79N. For example, if the sacrificial material layers 42 include silicon nitride, the etch process can be a wet etch process in which the first exemplary structure is immersed within a wet etch tank including phosphoric acid, which etches silicon nitride selective to silicon oxide, silicon, and various other materials employed in the art. The memory opening fill structures 58 provide structural support while the laterally-extending cavities 43 are present within volumes previously occupied by the sacrificial material layers 42.

The laterally-extending cavities 43 expand laterally from around the narrow lateral isolation trench sections 79N until the laterally-extending cavities 43 merge into continuous laterally-extending void that continuously extend between neighboring pairs of narrow lateral isolation trench sections 79N within the areas of the memory array region 100. The first isotropic etch process isotropically recesses the sacrificial material layers 42 employing the narrow lateral isolation trench sections 79N as first conduits for a first isotropic etchant while the wide lateral isolation trench fill structures 76W prevent isotropic etchant access to the sacrificial material layers 42 through the wide lateral isolation trench sections 79W. In this case, the wide lateral isolation trench sections 79W are filled with the wide lateral isolation trench fill structures 76W during the first selective isotropic etch process.

In one embodiment shown in FIG. 17D, each of the laterally-extending cavities 43 may have a pair of laterally-convex sidewall sections 43S in a connection region 300 that is located between the memory array region 100 and the contact region 200. Each laterally-extending cavity 43 may have a portion located within the memory array region 100 and laterally extending between a respective pair of narrow lateral isolation trench sections 79N along the second horizontal direction hd2. The lateral extent of this portion along the second horizontal direction hd2 is herein referred to as a uniform word-line width, which is the width of a word line to be subsequently formed. In one embodiment, the uniform word-line width may correspond to a width of a memory block along the second horizontal direction hd2. In one embodiment, each of the laterally-extending cavities 43 has a variable width in the connection region 300 that changes from the uniform word-line width to zero with a lateral distance along the first horizontal direction hd1 from the memory array region 100 toward the contact region 200.

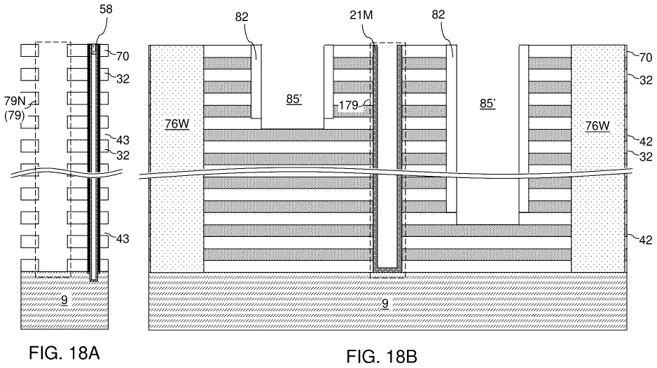

Referring to FIGS. 18A and 18B, an isotropic etch process can be performed to etch the sacrificial barrier liner 24L selectively to the material of the sacrificial access lateral isolation trench liners 21M. Sidewalls of the sacrificial access lateral isolation trench liners 21M can be physically exposed around the elongated voids within the access lateral isolation trenches 179. Further, top surface segments of the sacrificial material layers 42 may be exposed underneath the contact via cavities 85′.

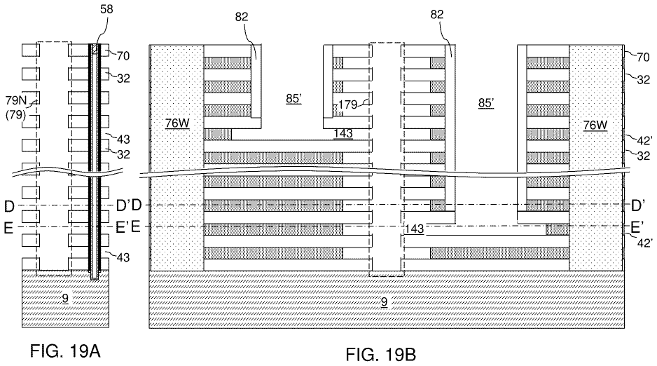

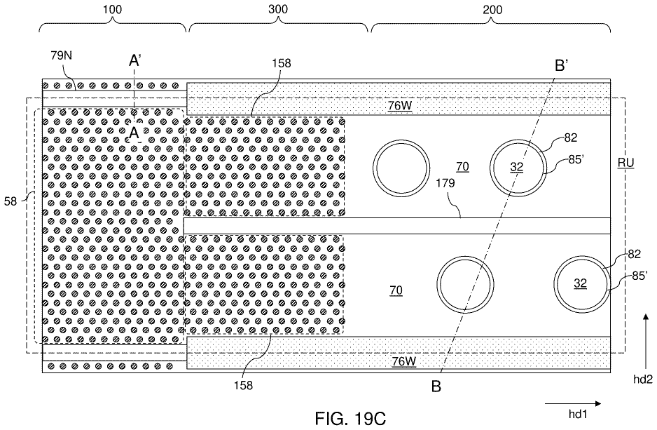

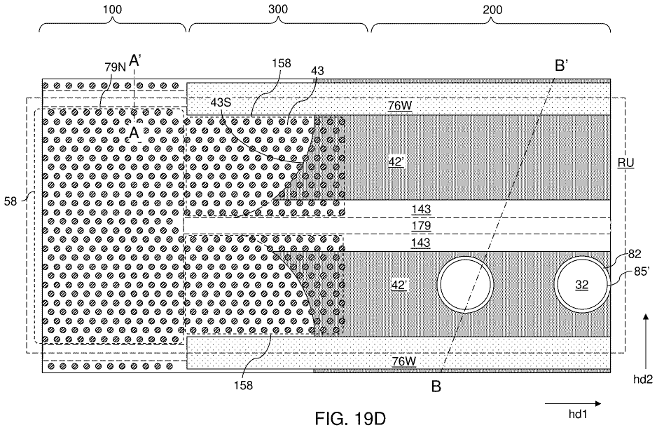

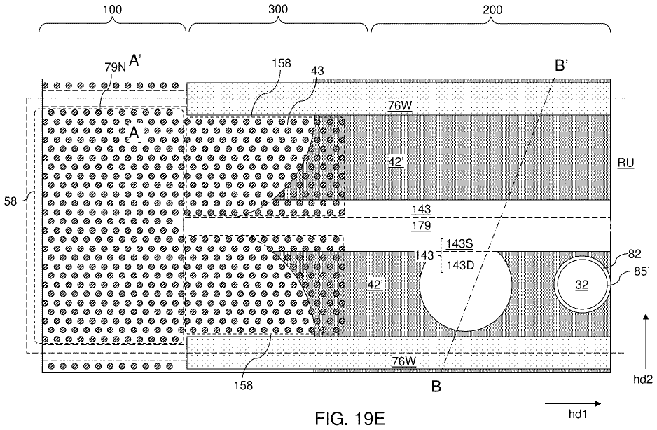

Referring to FIG. 19A-19E, a second selective isotropic etch process can be performed, which etches the materials of the sacrificial access lateral isolation trench liners 21M and the sacrificial material layers 42. The second selective isotropic etch process removes the entirety of the sacrificial access lateral isolation trench liners 21M, and laterally recesses physically exposed portions of the sacrificial material layers 42 by a second etch distance, which is less than the first etch distance and is less than the lateral distance between a neighboring pair of an access lateral isolation trench 179 and a wide lateral isolation trench fill structure 76W. Further, the second selective isotropic etch process etches portions of the sacrificial material layers 42 that are proximal to the contact via cavities 85′. Thus, the second selective isotropic etch process employs the access lateral isolation trenches 179 and the contact via cavities 85′ as conduits for an isotropic etchant that etches the materials of the sacrificial access lateral isolation trench liners 21M and the sacrificial material layers 42 in the contact region 200. The lateral recessing of the portions of the sacrificial material layers 42 from underneath the contact via cavities 85′ is isotropic. The duration of the second selective isotropic etch process is selected such that each of the cavities formed by removal of portions of the sacrificial material layers 42 from underneath the contact via cavities 85′ merges with a respective cavity that is formed by removal of a strip portion of a sacrificial material layer 42 around an access lateral isolation trench 179.

Generally, the sacrificial material layers 42 are isotropically recessed from around the access lateral isolation trenches 179 and the contact via cavities 85′ by the second lateral etch distance selectively to the materials of the insulating layers 32, the insulating cap layer 70, the tubular insulating spacers 82, the semiconductor material layer 9, and the material of the outermost layers of the memory films 50. Further, the laterally-extending cavities 43 can be laterally expanded during the second selective isotropic etch process. Connection cavities 143 are formed in volumes from which the sacrificial material layers 42 are removed around the access lateral isolation trenches 179 and the contact via cavities 85′. The second lateral etch distance is less than the lateral spacing between neighboring pairs of a respective access lateral isolation trench 179 and a wide lateral isolation trench fill structure 76W along the second horizontal direction hd2. Remaining portions of the sacrificial material layers 42 comprise dielectric material plates 42′.

The second selective isotropic etch process may comprise a wet etch process employing a wet etch solution, and/or may comprise a gas phase (dry) etch process in which the etchant is introduced in a vapor phase into the access lateral isolation trenches 179 and the contact via cavities 85′. For example, if the sacrificial material layers 42 include silicon nitride, the etch process can be a wet etch process in which the second exemplary structure is immersed within a wet etch tank including phosphoric acid, which etches silicon nitride selective to silicon oxide, silicon, and various other materials employed in the art. The memory opening fill structures 58 provide structural support while the laterally-extending cavities 43 are present within volumes previously occupied by the sacrificial material layers 42. The dielectric material plates 42′ provide structural support to remaining portions of the insulating layers 32 in the contact region 200. According to an aspect of the present disclosure, formation of support pillar structures in the contact region 200 is not necessary because the dielectric material plates 42′ provide structural support during the second selective isotropic etch process. Alternatively, support pillar structures (e.g., silicon oxide pillars) can be formed around the contact via cavities 85′ to provide additional support.

Each laterally-extending cavities 43 may be adjoined to a respective pair of connection cavities 143. The second isotropic etch process isotropically recesses the sacrificial material layers 42 employing the access lateral isolation trenches 179 and the contact via cavities 85′ as second conduits for a second isotropic etchant while the wide lateral isolation trench fill structures 76W prevent access by the isotropic etchant to the sacrificial material layers 42 through the wide lateral isolation trench sections 79W. In this case, the wide lateral isolation trench sections 79W are filled with the wide lateral isolation trench fill structures 76W during the second selective isotropic etch process.

In one embodiment, each of the laterally-extending cavities 43 may have a pair of laterally-convex sidewall sections 43S in a connection region 300 that is located between the memory array region 100 and the contact region 200. Each laterally-extending cavity 43 may have a portion located within the memory array region 100 and laterally extending between a respective pair of narrow lateral isolation trench sections 79N along the second horizontal direction hd2.

As shown in FIG. 19E, each of the connection cavities 143 may comprise a strip cavity portion 143S laterally extending along the first horizontal direction hd1 and having a uniform strip width along the second horizontal direction hd2 in the contact region 200. The uniform strip width is less than the uniform word line width. Further, each of the connection cavities 143 may comprise a disc-shaped cavity portion 143D that underlies a respective contact via cavity 85′ and is adjoined to the strip cavity portion 143S. A vertical stack of dielectric material plates 42′ may be vertically interlaced with the insulating layers 32. Each of the dielectric material plates 42′ may be laterally bounded by a respective laterally-extending cavity 43, a respective connection cavity 143, and a respective wide lateral isolation trench fill structure 76W.

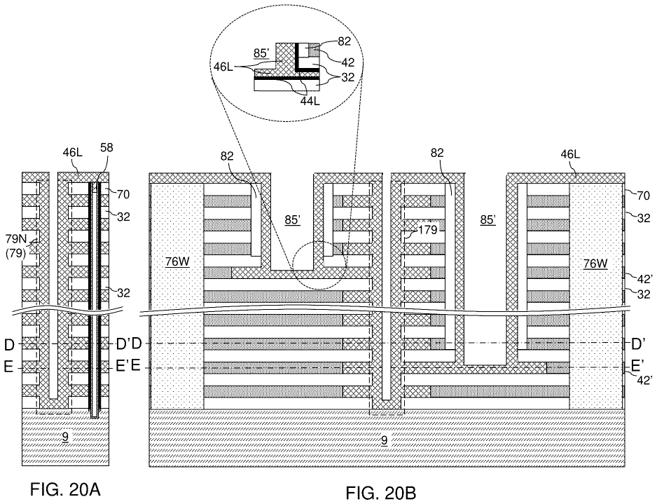

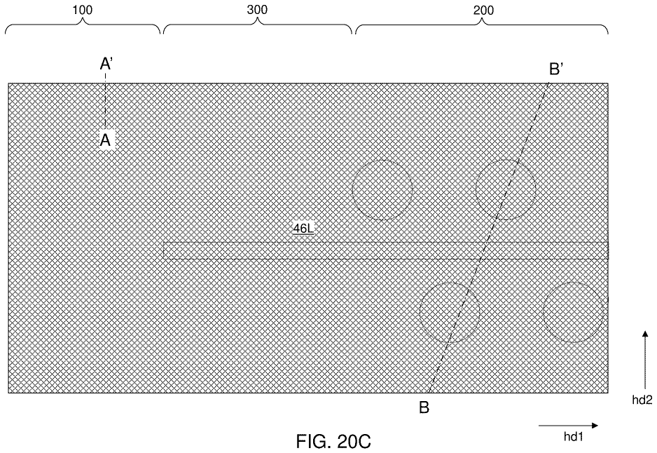

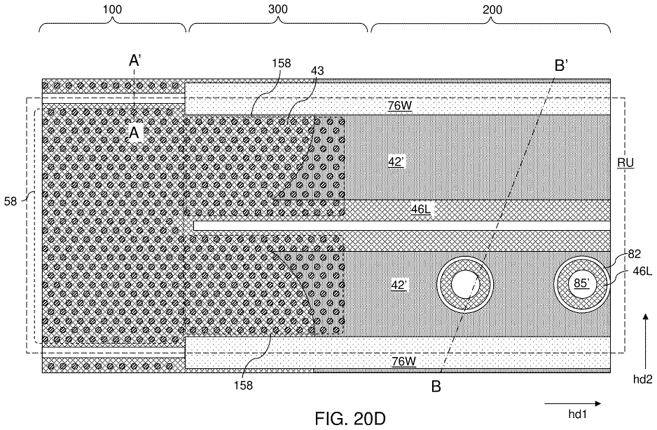

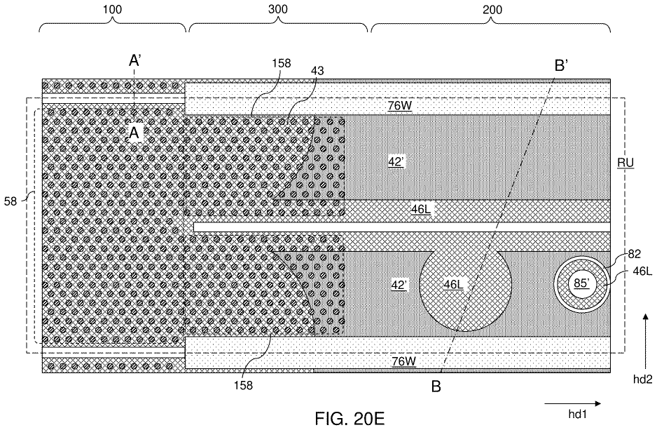

Referring to FIG. 20A-20E, an optional continuous backside blocking dielectric layer 44L may be conformally deposited into peripheral portions of the laterally-extending cavities 43, the connection cavities 143 and the contact via cavities 85′, as shown in the inset of FIG. 20B. The backside blocking dielectric layer 44L does not completely fill the cavities (43, 143, 85′). The backside blocking dielectric layer 44L may comprise any suitable dielectric material, such as a metal oxide dielectric layer, for example an aluminum oxide layer. At least one conductive material, such as a combination of a metallic barrier liner material and a metal fill material, may be conformally deposited in the laterally-extending cavities 43, the connection cavities 143, peripheral portions of the contact via cavities 85′, and over the insulating cap layer 70 to form a continuous electrically conductive layer 46L. If the continuous backside blocking dielectric layer 44L is present, then the continuous electrically conductive layer 46L is formed on the backside blocking dielectric layer 44L. The metallic barrier liner material may comprise a conductive metallic compound material such as TiN, TaN, WN, MoN, TiC, TaC, WC, alloys thereof, or a combination thereof. The metal fill material may comprise W, Ti, Ta, Mo, Co, Ru, Cu, alloys thereof, or combinations thereof. The total thickness of the at least one conductive material in regions that are not vertically bounded by a pair of an overlying insulating layer 32 and an underlying insulating layer 32 is greater than one half of the height of the laterally-extending cavities 43 and the connection cavities 143.

In one embodiment, each portion of the continuous electrically conductive layer 46L that is exposed to an overlying contact via cavity 85′ may have the same thickness as a tubular portion of the continuous electrically conductive layer 46L that is formed in the periphery of the overlying contact via cavity 85′. This thickness is greater than one half of the vertical spacing between vertically neighboring pairs of insulating layers 32, and may be less than or may be greater than the vertical spacing between vertically neighboring pairs of insulating layers 32. Generally, the continuous electrically conductive layer 46L comprises at least one electrically conductive material having a unform material composition throughout and is free of any material interface therein. As used herein, a material interface refers to an interface at which two different material are in direct contact with each other. For example, the metallic barrier liner material may have a unform material composition throughout and may be free of any material interface therein. Likewise, the metal fill material may have a unform material composition throughout and may be free of any material interface therein.

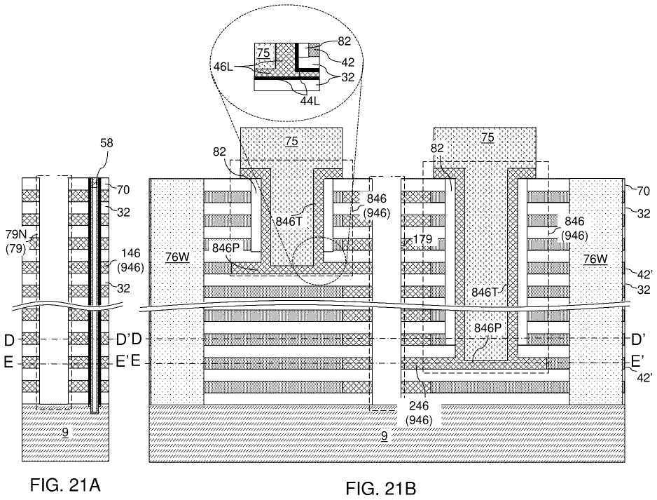

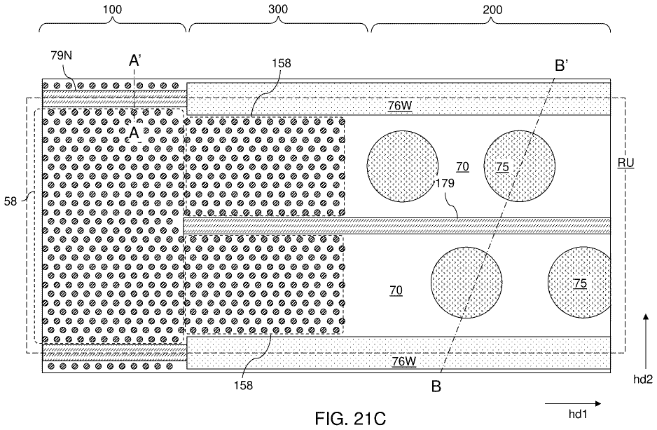

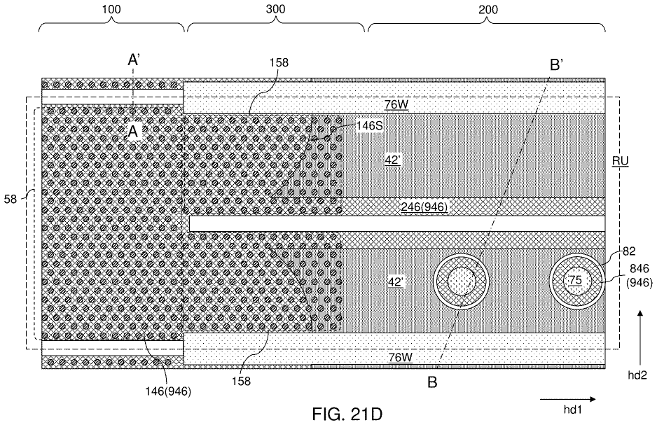

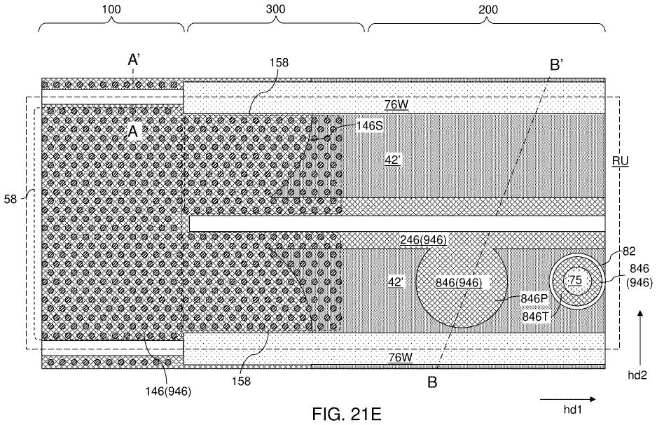

Referring to FIG. 21A-21E, a photoresist layer may be applied over the first exemplary structure, and may be lithographically patterned to form photoresist material portions 75 covering the areas of the contact via openings 85′. Unmasked portions of the continuous electrically conductive layer 46L can be isotropically etched to pattern the continuous electrically conductive layer 46L. Specifically, portions of the continuous electrically conductive layer 46L that are present in the narrow lateral isolation trench sections 79N, in the access lateral isolation trenches 179, or above the horizontal plane including the top surface of the insulating cap layer 70 and not covered by the photoresist material portions 75 can be removed during a selective etch process that etches materials of the continuous electrically conductive layer 46L selectively to the materials of the insulating layers 32, the insulating cap layer 70, and the semiconductor material layer 9.

The patterned portions of the continuous electrically conductive layer 46L comprise integrated word line and contact via structures 946. The integrated word line and contact via structures 946 are formed in the cavities (43, 143) that are formed by the first isotropic etch process and the second isotropic etch process. As shown in FIG. 21E, each of the integrated word line and contact via structures 946 comprises a respective horizontally-extending word line 146, a respective contact via structure 846, and a respective horizontally-extending lateral connection strip 246 connecting the respective horizontally-extending word line 146 and the respective contact via structure 846.

If the continuous backside blocking dielectric layer 44L is present, then it is separated into separate backside blocking dielectric layers 44, as shown in the inset in FIG. 21B. Since the backside blocking dielectrics 44 are not removed at the intersections of the word lines 146, the connection strips 246 and the contact via structures 846, the chance of word line 146 breakdown is reduced.

As shown in FIG. 21B, the contact via structure 846 includes an annular vertically-extending tubular portion 846T and an underlying horizontally-extending bottom plate portion 846P which extends beyond the sidewall of the tubular portion 846T and contacts the lateral connection strip 246. The respective tubular portion 846T has a bottom end that is connected to the respective bottom plate 846P. In one embodiment, a center portion of the respective bottom plate 846P has a uniform inner bottom plate thickness; the respective tubular portion 846T has a uniform lateral thickness between an inner sidewall and an outer sidewall; and the uniform lateral thickness is the same as the uniform inner bottom plate thickness.

The insulating layers 32 are vertically spaced apart from each other and are interlaced with the horizontally-extending word lines 146 (and optionally with the backside blocking dielectric layers 44) to provide a vertically alternating sequence (32, 146) of the insulating layers 32 and the horizontally-extending word lines 146. Each of the horizontally-extending word lines 146 laterally extend along a first horizontal direction hd1 and have a uniform word-line width along a second horizontal direction hd2 in a memory array region 100. The lateral connection strips 246 laterally extend along the first horizontal direction hd1 and have a uniform strip width along the second horizontal direction hd2 in a contact region 200. The uniform strip width is less than the uniform word line width. Drain side select gate electrodes may overlie the word lines 146 and source side select gate electrodes may underlies the word lines 146.

In one embodiment shown in FIGS. 21D and 21E, each of the horizontally-extending word lines 146 has a laterally-convex sidewall section 146S in a connection region 300 that is located between the memory array region 100 and the contact region 200. In one embodiment, each of the horizontally-extending word lines 146 has a variable width that changes from the uniform word-line width to the uniform strip width within the connection region 300 containing the laterally-convex sidewall sections 146S.

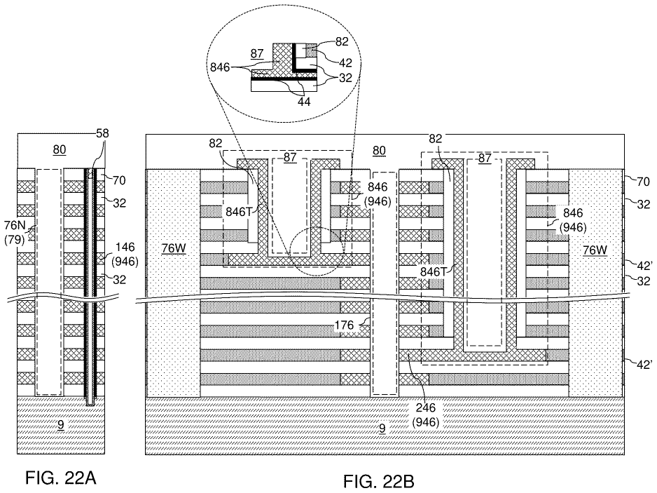

Referring to FIGS. 22A and 22B, a second dielectric fill material may be conformally deposited in the narrow lateral isolation trench sections 79N, in the access lateral isolation trenches 179, and over the insulating cap layer 70 to form a continuous dielectric material portion. The continuous dielectric material portion includes a contact-level dielectric layer 80 that is located above the insulating cap layer 79, lateral isolation trench fill structures (76N, 176) filling the lateral isolation trenches (79N, 179), and dielectric pillar material portions 87 that are laterally surrounded by the contact via structures 846. Each of the tubular portions 846T of the contact via structures 846 laterally encloses a respective dielectric pillar material portion 87.

In one embodiment, the contact-level dielectric layer 80 overlies the vertically alternating sequence (32, 146) and the tubular portions 846T of the contact via structures 846. The contact-level dielectric layer 80 and the dielectric pillar material portions 87 are portions of a dielectric material having a uniform material composition throughout. Additional portions of the dielectric material comprise lateral isolation trench fill structures (76N, 176) contacting sidewalls of each of the insulating layers 32 and each of the horizontally-extending word lines 146. The lateral isolation trench fill structures (76N, 176) comprise narrow lateral isolation trench fill structures 76N that are formed in the narrow lateral isolation trench sections 79N and access lateral isolation trench fill structures 176 that are formed in the access lateral isolation trenches 179. Thus, the continuous dielectric material portion having a uniform material composition throughout may comprise: a contact-level dielectric layer 80 overlying each of the vertically alternating sequences (32, 146); and narrow lateral isolation trench fill structures 76N which are vertically-extending portions that vertically extend downward from the contact-level dielectric layer 80 and filling at least the narrow lateral isolation trench sections 79N. In one embodiment, the lateral connection strips 246 of the integrated word line and contact via structures 846 are in direct contact with the vertically-extending portions of the continuous dielectric material portion.

In one embodiment, the wide lateral isolation trench fill structures 76W may comprise the same or a different dielectric material than the continuous dielectric material portion. In one embodiment, each access lateral isolation trench 179 is laterally spaced from the dual-width lateral isolation trenches 79. Access isolation trench fill structures 176 can fill the access lateral isolation trenches 179. The lateral connection strips 246 of the integrated word line and contact via structures 946 are in contact with a sidewall of a respective one of the access isolation trench fill structures 176.

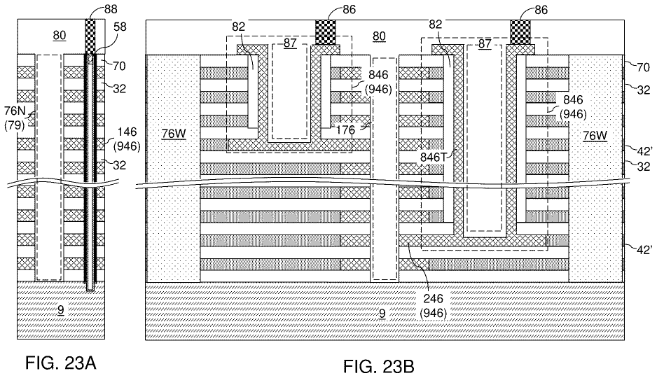

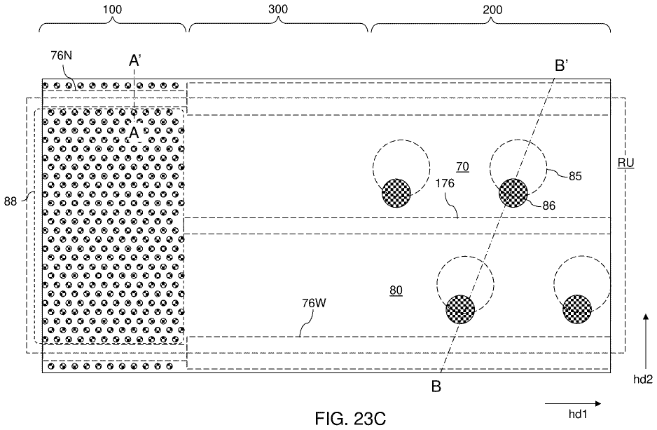

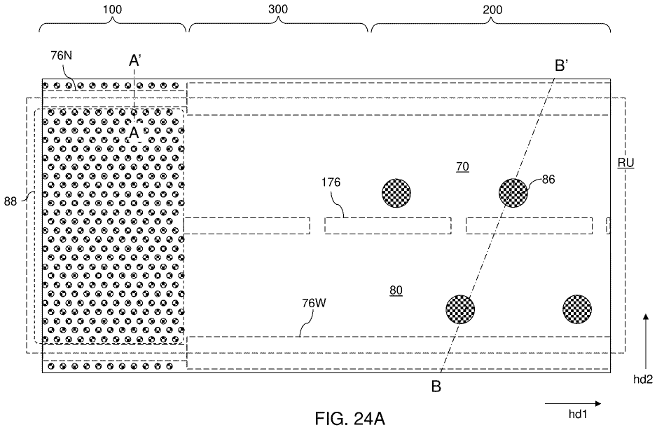

Referring to FIG. 23A-23C, various conductive via structures (88, 86) can be formed through the contact-level dielectric layer 80. For example, drain contact via structures 88 can be formed through the contact-level dielectric layer 80 on the drain regions 63 of the memory opening fill structures 58. Drain contact via structures preferably do not contact the dummy memory opening fill structures 158. Connection via structures 86 may be formed through the contact-level dielectric layer 80 on an annular top portion (e.g., the tubular portion 846T) of a respective one of the contact via structures 846 that overlies the horizontal plane including the top surface of the insulating cap layer 70.

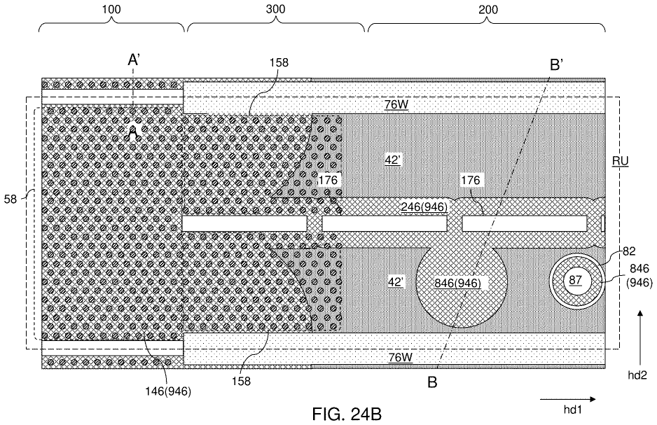

Referring to FIGS. 24A and 24B, an alternative configuration of the first exemplary structure is illustrated, which can be derived from the first exemplary structure by forming a plurality of access lateral isolation trenches 179 that are arranged along the first horizontal direction hd1 instead of each single continuous access lateral isolation trench 179 located between a respective neighboring pair of dual-width lateral isolation trenches 79. In this case, a row of access lateral isolation trench fill structures 176 may be formed between each neighboring pair of wide lateral isolation trench fill structures 76W.

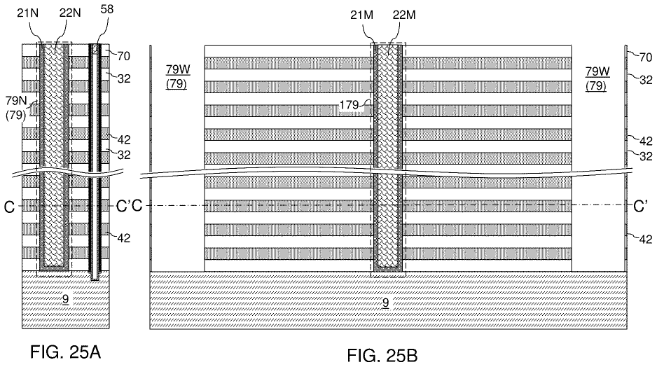

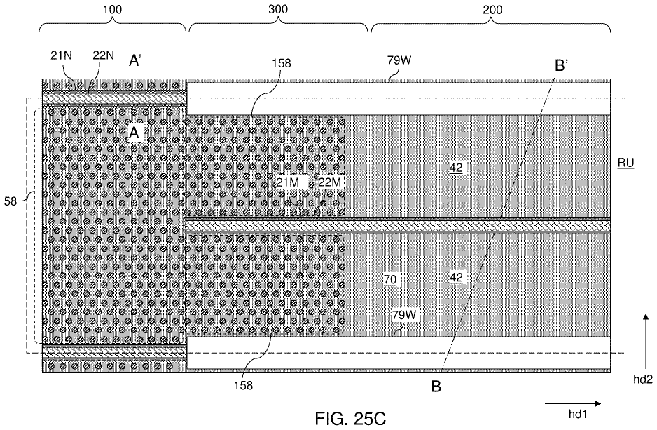

Referring to FIG. 25A-25C, a second exemplary structure according to a second embodiment of the present disclosure is illustrated, which may be the same as the first exemplary structure illustrated in FIGS. 7A and 7B.

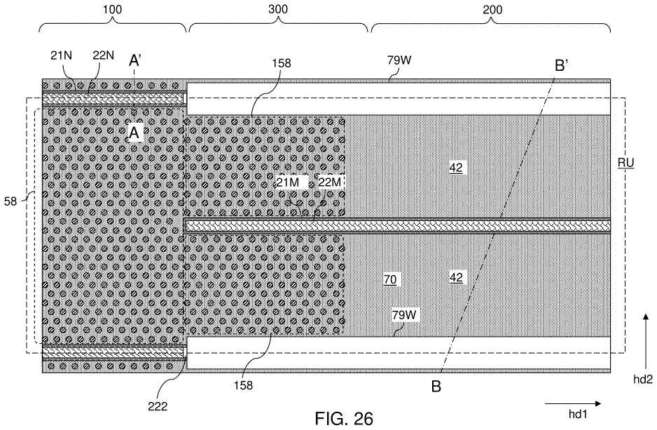

Referring to FIG. 26, an oxidation process may be performed to convert exposed surface portions (i.e., sidewalls) of the sacrificial narrow isolation trench fill structures 22N into sacrificial oxide liners 222. If the sacrificial narrow isolation trench fill structure 22N comprises amorphous silicon or polysilicon, then the sacrificial oxide liners 222 comprise silicon oxide liners that are formed by oxidation of the exposed sidewalls of the silicon structures 22N in the wide lateral isolation trench sections 79W.

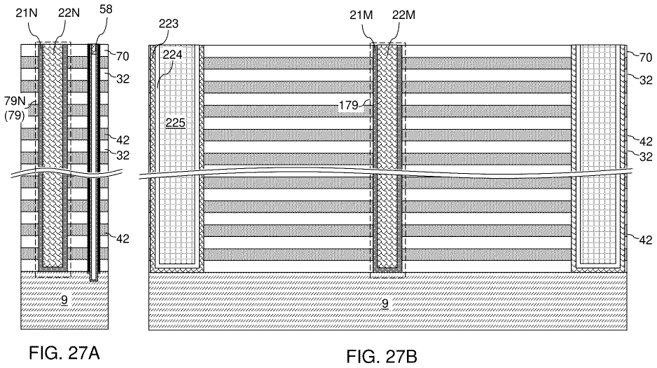

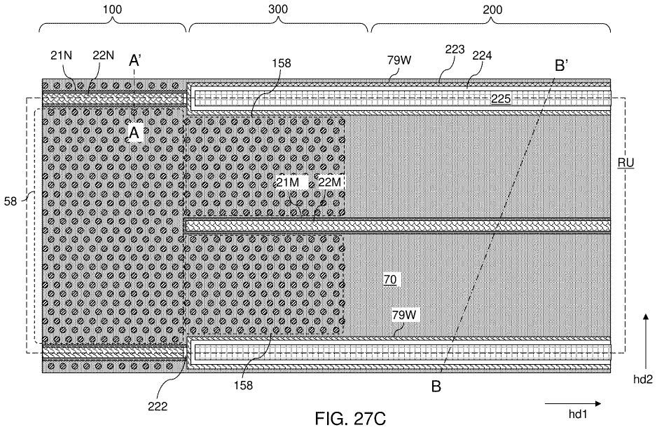

Referring to FIG. 27A-27C, a first sacrificial trench liner 223, a second sacrificial trench liner 224, and a wide sacrificial trench fill structure 225 may be formed within each wide lateral isolation trench section 79W. For example, a first continuous sacrificial trench liner including a first sacrificial trench liner material (such as amorphous silicon or polysilicon), a second continuous sacrificial trench liner including a second sacrificial trench liner material (such as silicon nitride), and a sacrificial trench fill material (such as amorphous silicon or polysilicon) may be sequentially deposited to fill the entire volumes of the wide lateral isolation trench sections 79W, and portions of the first continuous sacrificial trench liner, the second continuous sacrificial trench liner, and the sacrificial trench fill material that overlie the horizontal plane including the top surface of the insulating cap layer 70 may be removed by performing a chemical mechanical polishing process. Top surfaces of the sacrificial narrow isolation trench fill structure 22N may be physically exposed after the chemical mechanical polishing process. Remaining portions of the first continuous sacrificial trench liner, the second continuous sacrificial trench liner, and the sacrificial trench fill material comprise the first sacrificial trench liners (e.g., silicon liners) 223, the second sacrificial trench liners (e.g., silicon nitride liners) 224, and the wide sacrificial trench fill structures (e.g., silicon structures) 225.

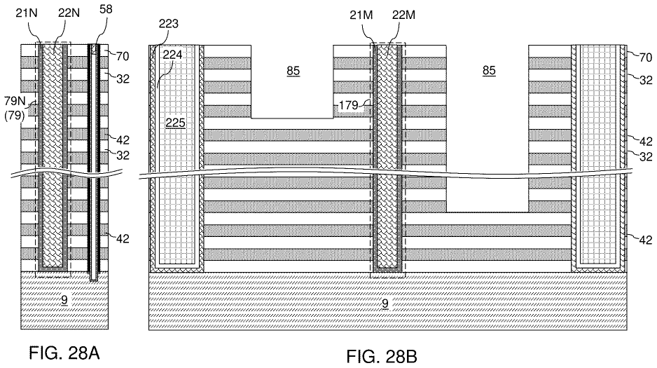

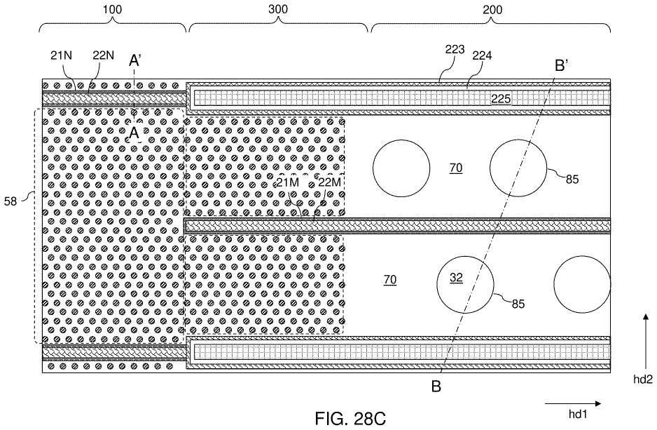

Referring to FIG. 28A-28C, the processing steps described with reference to FIGS. 9A-9C can be performed to form the contact via openings 85.

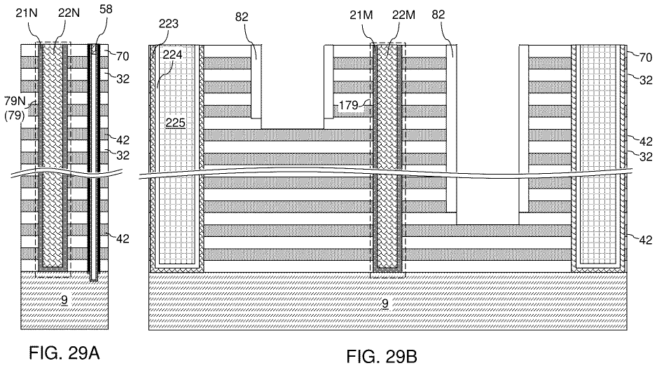

Referring to FIGS. 29A and 29B, the processing steps described with reference to FIGS. 10A and 10B can be performed to form tubular insulating spacers 82 and to vertically extend contact via cavities 85′.

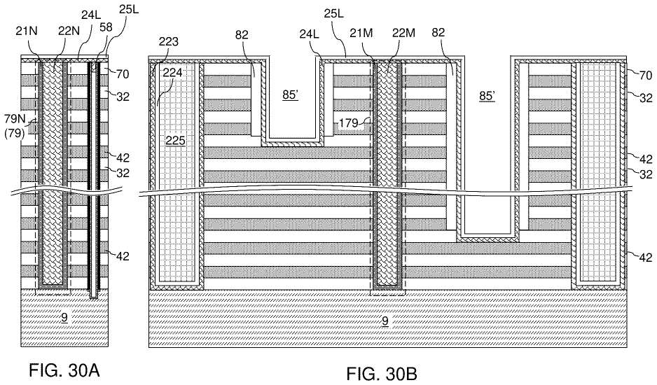

Referring to FIGS. 30A and 30B, the processing steps described with reference to FIGS. 12A, 12B, 13A, and 13B can be performed to form a sacrificial barrier liner 24L and a sacrificial dielectric liner 25L.

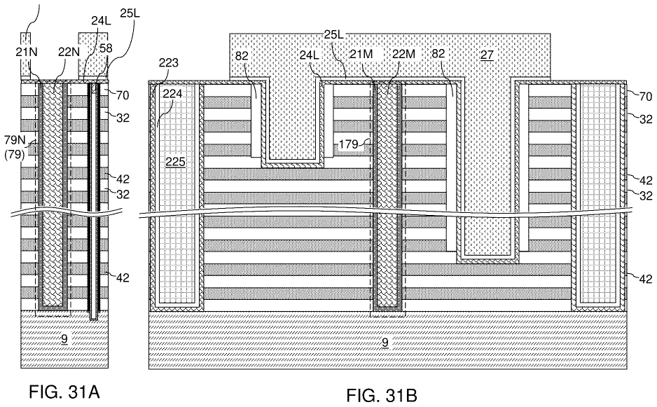

Referring to FIGS. 31A and 31B, the processing steps described with reference to FIGS. 14A and 14B can be performed with a modification in the pattern of the photoresist layer 27. Specifically, the photoresist layer 27 can be applied over the second exemplary structure, and can be lithographically patterned to form openings over the areas of the dual-width lateral isolation trenches 79 while covering areas outside of the dual-width lateral isolation trenches 79 in a plan view. A first etch process can be performed to remove unmasked portions of the sacrificial dielectric liner 25L selectively to the material of the sacrificial barrier liner 24L. Each portion of the sacrificial dielectric liner 25L overlying the dual-width lateral isolation trenches 79 may be removed, and surfaces of the sacrificial barrier liner 24L may be physically exposed within the areas of the dual-width lateral isolation trenches 79.

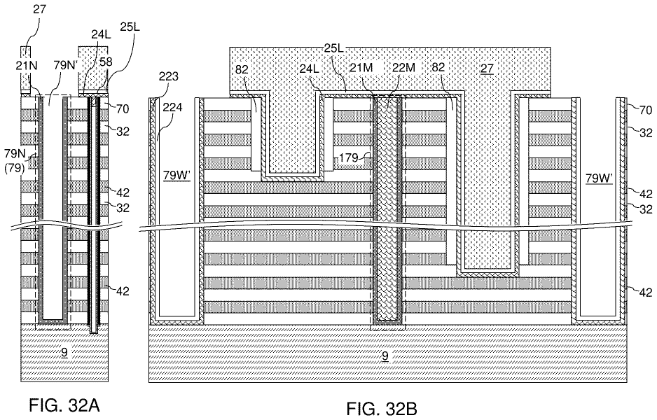

Referring to FIGS. 32A and 32B, a second etch process can be performed to remove unmasked portions of the sacrificial barrier liner 24L, the sacrificial narrow isolation trench fill structure 22N, and the wide sacrificial trench fill structure 225 selectively to the materials of the sacrificial narrow trench liners 21N and the second sacrificial trench liner 224. Surfaces of the sacrificial narrow trench liners 21N are physically exposed in the narrow lateral isolation trench sections 79N, and surfaces of the second sacrificial trench liners 224 are physically exposed in the wide lateral isolation trench sections 79W.

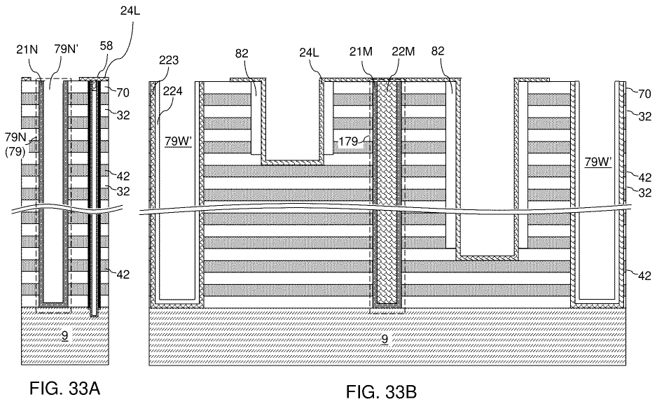

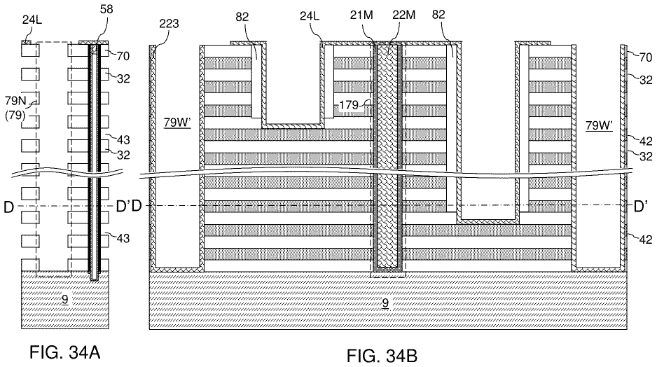

Referring to FIGS. 33A and 33B, the photoresist layer 27 can be subsequently removed, for example, by ashing. Remaining portions of the sacrificial dielectric liner 25L and sacrificial oxide liners 222 (e.g., the silicon oxide liners 25L and 222) may be removed by selective etching relative to the sacrificial narrow trench liners 21N and the second sacrificial trench liners 224 (e.g., the silicon nitride liners 21N and 224).

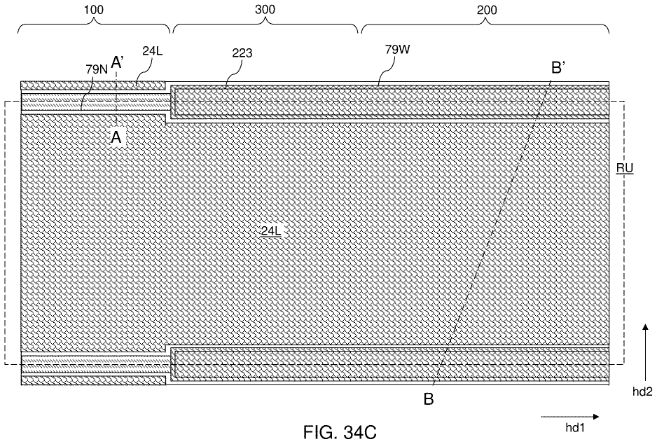

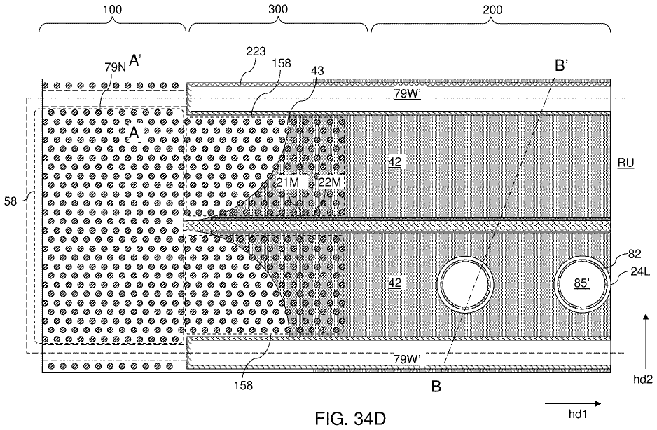

Referring to FIG. 34A-34D, the processing steps described with reference to FIG. 17A-17D can be performed. Specifically, a first selective isotropic etch process can be performed, which etches the materials of the sacrificial narrow trench liners 21N, the second sacrificial trench liners 224 and the sacrificial material layers 42. In one embodiment, the sacrificial narrower trench liners 21N, the second sacrificial trench liners 224 and the sacrificial material layers 42 may comprise the same material, such as silicon nitride. The first selective isotropic etch process removes the entirety of the sacrificial narrow trench liners 21N and the second sacrificial trench liners 224, laterally recesses physically exposed portions of the sacrificial material layers 42 by a first etch distance, and etches portions of the sacrificial access lateral isolation trench liners 21M. The first sacrificial trench liners (e.g., silicon liners) 223 remain in the wide lateral isolation trench sections 79W′.

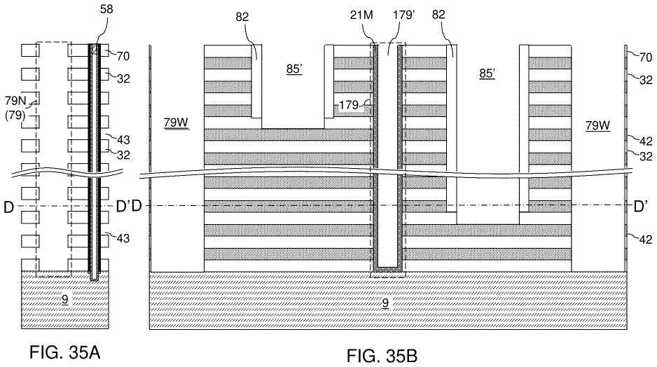

Referring to FIGS. 35A and 35B, an isotropic etch process can be performed to etch the sacrificial barrier liner 24L, the first sacrificial trench liners 223 and the sacrificial access lateral isolation trench fill structures 22M (i.e., the silicon liners and structures 24L, 223 and 22M) selectively to the materials of the sacrificial access lateral isolation trench liners 21M, the insulating layers 32, and the sacrificial material layers 42. Sidewalls of the sacrificial access lateral isolation trench liners 21M can be physically exposed around the wall-shaped voids within the access lateral isolation trenches 179. Further, top surface segments of the sacrificial material layers 42 may be exposed underneath the contact via cavities 85′.

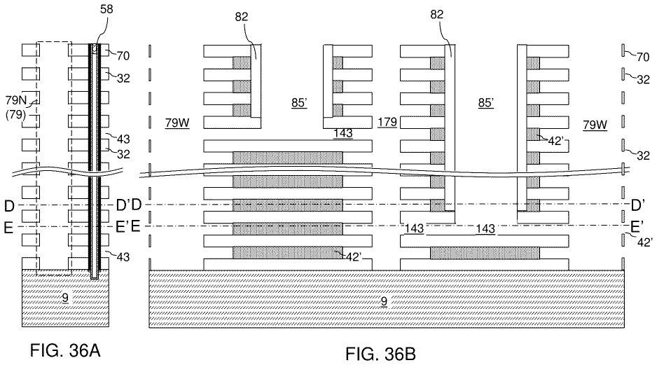

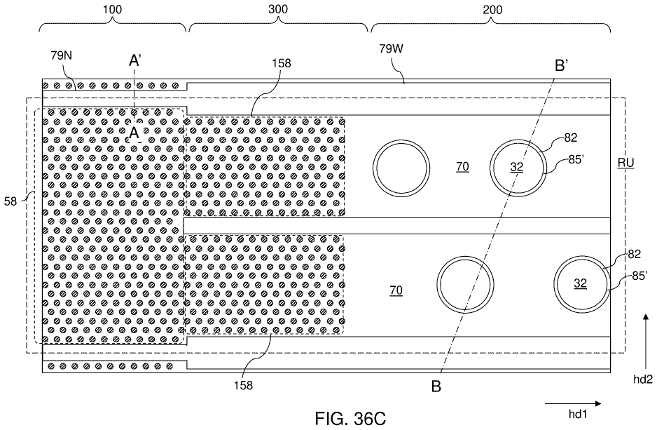

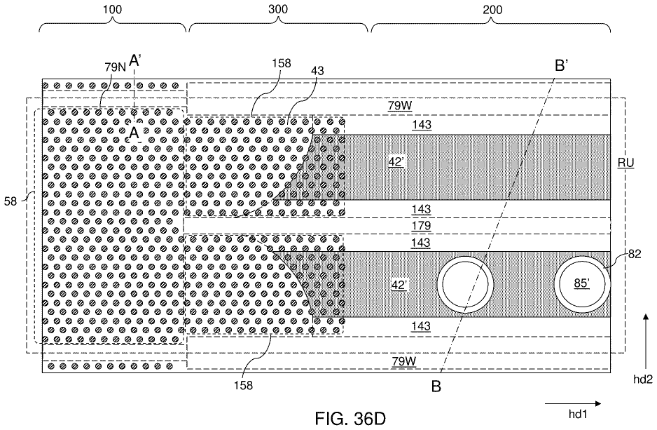

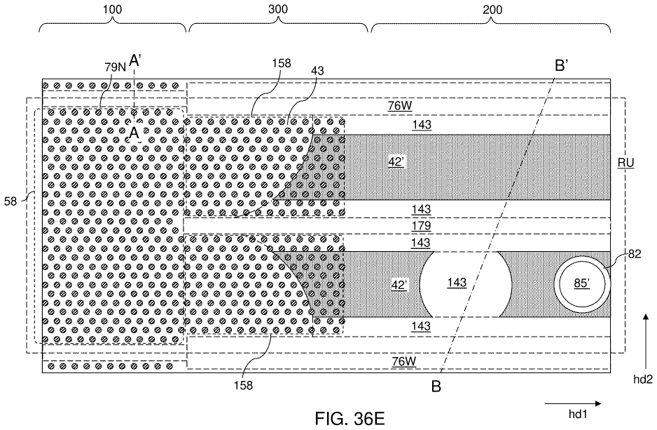

Referring to FIG. 36A-36E, a second selective isotropic etch process can be performed, which etches the materials of the sacrificial access lateral isolation trench liners 21M and the sacrificial material layers 42. The second selective isotropic etch process removes the entirety of the sacrificial access lateral isolation trench liners 21M, and laterally recesses physically exposed portions of the sacrificial material layers 42 by a second etch distance, which is less than the first etch distance. The second selective isotropic etch process etches portions of the sacrificial material layers 42 that are proximal to the wide lateral isolation trench sections 79W and further recesses the concave sidewalls of the sacrificial material layers 42 that are located in the connection region 300. Further, the second selective isotropic etch process etches portions of the sacrificial material layers 42 that are proximal to the contact via cavities 85′. Thus, the second selective isotropic etch process employs the dual-width lateral isolation trenches 79, the access lateral isolation trenches 179, and the contact via cavities 85′ as conduits for an isotropic etchant that etches the materials of the sacrificial access lateral isolation trench liners 21M and the sacrificial material layers 42. The lateral recessing of the portions of the sacrificial material layers 42 from underneath the contact via cavities 85′ is isotropic. The duration of the second selective isotropic etch process is selected such that each of the cavities formed by removal of portions of the sacrificial material layers 42 from underneath the contact via cavities 85′ merges with a respective cavity that is formed by removal of a strip portion of a sacrificial material layer 42 around an access lateral isolation trench 179.

In the second embodiment, the sacrificial material layers 42 are isotropically recessed from around the dual-width lateral isolation trenches 79, the access lateral isolation trenches 179, and the contact via cavities 85′ by the second lateral etch distance selectively to the materials of the insulating layers 32, the insulating cap layer 70, the tubular insulating spacers 82, the semiconductor material layer 9, and the material of the outermost layers of the memory films 50. Further, the laterally-extending cavities 43 can be laterally expanded during the second selective isotropic etch process. Connection cavities 143 are formed in volumes from which the sacrificial material layers 42 are removed around the access lateral isolation trenches 179 and the contact via cavities 85′. The second lateral etch distance is less than the lateral spacing between neighboring pairs of a respective access lateral isolation trench 179 and a wide lateral isolation trench section 79W along the second horizontal direction hd2. Remaining portions of the sacrificial material layers 42 comprise dielectric material plates 42′.

The second selective isotropic etch process may comprise a wet etch process employing a wet etch solution, and/or may comprise a gas phase (dry) etch process in which the etchant is introduced in a vapor phase into the narrow lateral isolation trench sections 79N, the wide lateral isolation trench section 79W and the access lateral isolation trench 179. For example, if the sacrificial material layers 42 include silicon nitride, the etch process can be a wet etch process in which the second exemplary structure is immersed within a wet etch tank including phosphoric acid, which etches silicon nitride selective to silicon oxide, silicon, and various other materials employed in the art. The memory opening fill structures 58 provide structural support while the laterally-extending cavities 43 are present within volumes previously occupied by the sacrificial material layers 42. The dielectric material plates 42′ provide structural support to remaining portions of the insulating layers 32 in the contact region 200.

Each laterally-extending cavity 43 may be adjoined to a respective pair of connection cavities 143, as shown in FIGS. 36D and 36E. The second isotropic etch process isotropically recesses the sacrificial material layers 42 employing the dual-width lateral isolation trenches 79, the access lateral isolation trenches 179 and the contact via cavities 85′ as second conduits for a second isotropic etchant.

As shown in FIG. 36E, each of the connection cavities 143 may comprise a pair of strip cavity portions laterally extending along the first horizontal direction hd1 and having a respective uniform strip width along the second horizontal direction hd2 in the contact region 200. The uniform strip widths are less than the uniform word line width. Further, each of the connection cavities 143 may comprise a disc-shaped cavity portion that underlies a respective contact via cavity 85′ and is adjoined to the strip cavity portions. A vertical stack of dielectric material plates 42′ may be vertically interlaced with the insulating layers 32.

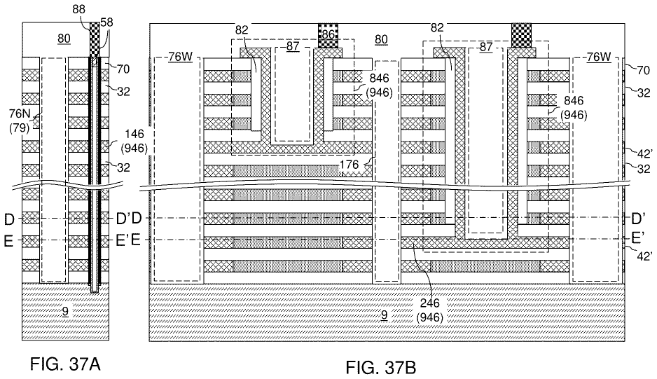

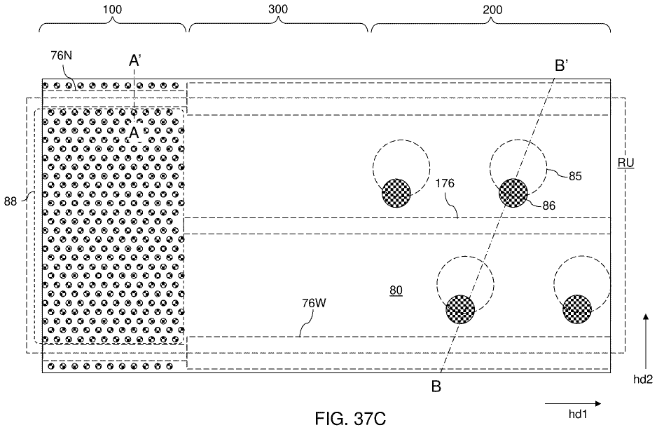

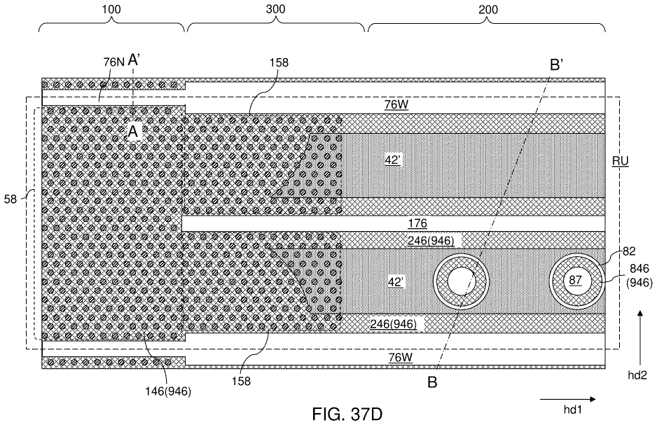

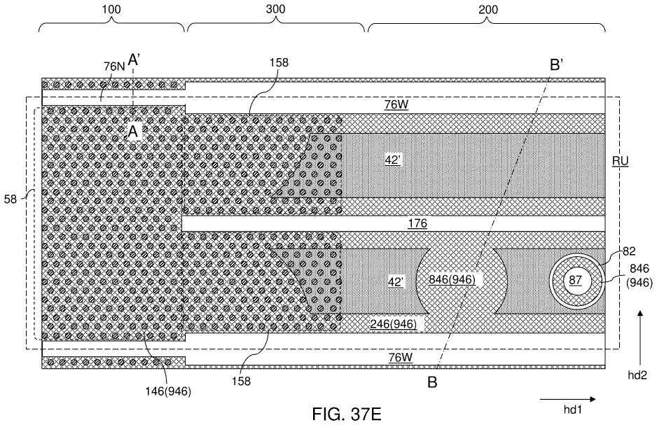

Referring to FIG. 37A-37E, the processing steps described with reference to FIG. 20A-23C can be performed to form integrated word line and contact via structures 946, a contiguous dielectric material portion (80, 76N, 76W, 87), and conductive via structures (88, 86). The integrated word line and contact via structures 946 are formed in the cavities (43, 143) that are formed by the first isotropic etch process and the second isotropic etch process. Each of the integrated word line and contact via structures 946 comprises a respective horizontally-extending word line 146, a respective contact via structure 846, and a respective pair of lateral connection strips 246 connecting the respective horizontally-extending word line 146 and the respective contact via structure 846.

The contiguous dielectric material portion (80, 76N, 76W, 87) comprises a dielectric fill material that is conformally deposited in the narrow lateral isolation trench sections 79N, in the wide lateral isolation trench sections 79W, in the access lateral isolation trenches 179, and over the insulating cap layer 70 to form a continuous dielectric material portion. The continuous dielectric material portion includes a contact-level dielectric layer 80 that is located above the insulating cap layer 79, lateral isolation trench fill structures (76N, 76W, 176) filling the lateral isolation trenches (79, 179), and dielectric pillar material portions 87 that are laterally surrounded by the contact via structures 846. Each of the tubular portions of the contact via structures 846 laterally encloses a respective dielectric pillar material portion 87.

In one embodiment, the contact-level dielectric layer 80 overlies the vertically alternating sequence (32, 146) and the tubular portions of the contact via structures 86. The contact-level dielectric layer 80 and the dielectric pillar material portions 87 are portions of a dielectric material having a uniform material composition throughout. Additional portions of the dielectric material comprise lateral isolation trench fill structures (76N, 76W, 176) contacting sidewalls of each of the insulating layers 32 and each of the horizontally-extending word lines 146. The lateral isolation trench fill structures (76N, 76W, 176) comprise narrow lateral isolation trench fill structures 76N that are formed in the narrow lateral isolation trench sections 79N, wide lateral isolation trench fill structures 76W that are formed in the wide lateral isolation trench sections 79W, and access lateral isolation trench fill structures 176 that are formed in the access lateral isolation trenches 179.

In one embodiment, the lateral connection strips 246 of the integrated word line and contact via structures 946 are in direct contact with a vertically-extending portion (such as a wide lateral isolation trench fill structures 76W or an access lateral isolation trench fill structure 176) of the continuous dielectric material portion (80, 76N, 76W, 87).

In one embodiment, each access lateral isolation trench that 179 is laterally spaced from the dual-width lateral isolation trenches 79. Access isolation trench fill structures 176 can fill the access lateral isolation trenches 179. The lateral connection strips 246 of the integrated word line and contact via structures 946 are in contact with a sidewall of a respective one of the access isolation trench fill structures 176. In one embodiment, the lateral connection strips 246 of the integrated word line and contact via structures 946 are in contact with a sidewall of the vertically-extending portion (such as a of the continuous dielectric material portion (80, 76N, 76W, 87)).

The various conductive via structures (88, 86) can be formed through the contact-level dielectric layer 80. For example, drain contact via structures 88 can be formed through the contact-level dielectric layer 80 on the drain regions 63. Connection via structures 86 may be formed through the contact-level dielectric layer 80 on an annular top portion of a respective one of the contact via structures 846 that overlies the horizontal plane including the top surface of the insulating cap layer 70.

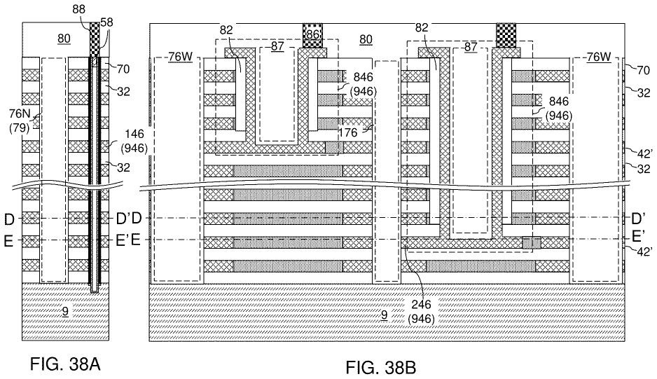

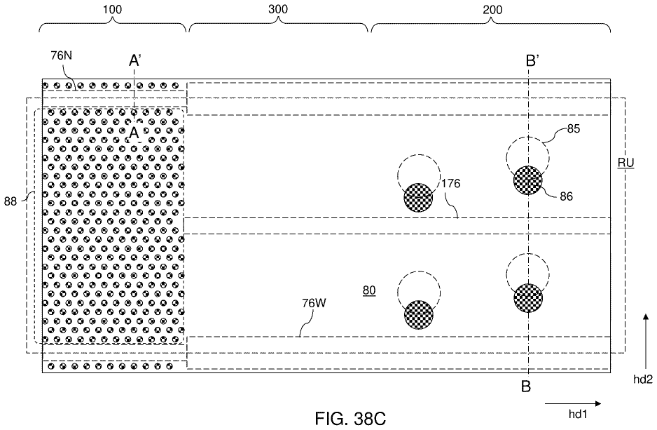

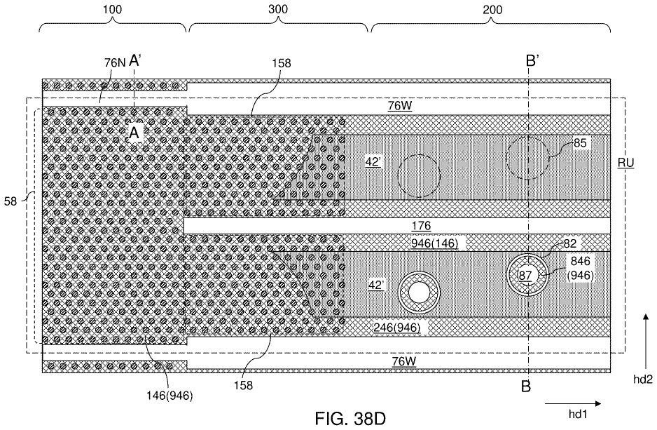

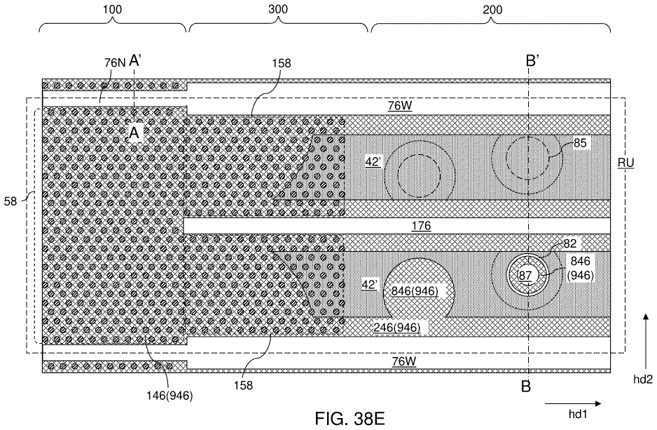

Referring to FIG. 38A-38E, a first alternative configuration of the second exemplary structure can be derived from the second exemplary structure described above by staggering the contact via openings 85 along the second horizontal direction hd2 such that each contact via structure 846 is in direct contact with only one lateral connection strip 246, as shown in FIG. 38E.

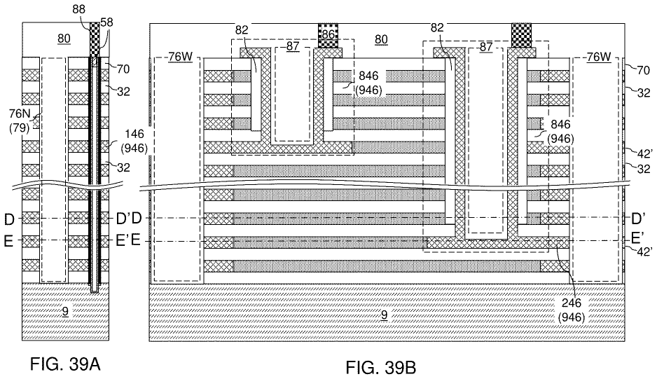

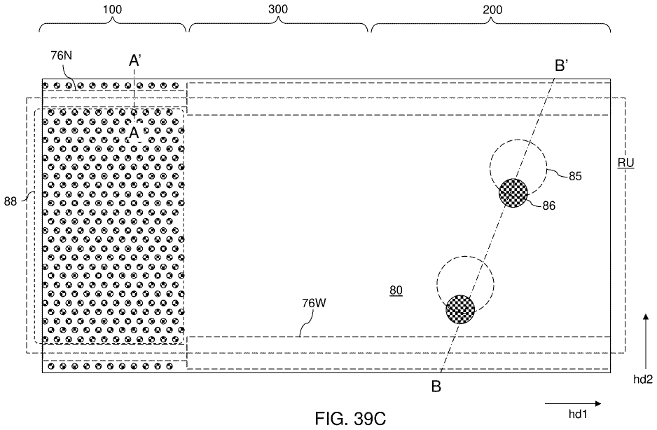

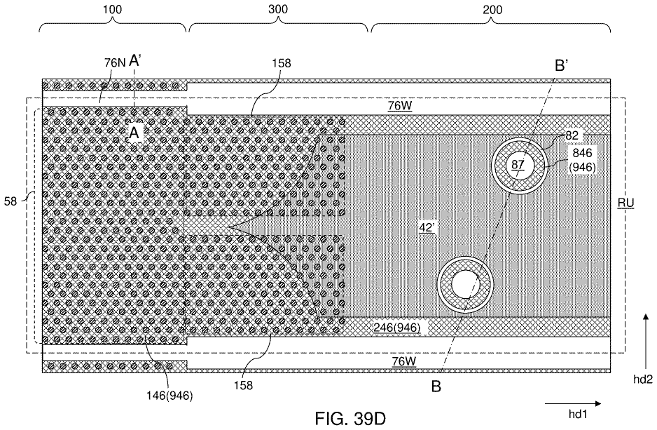

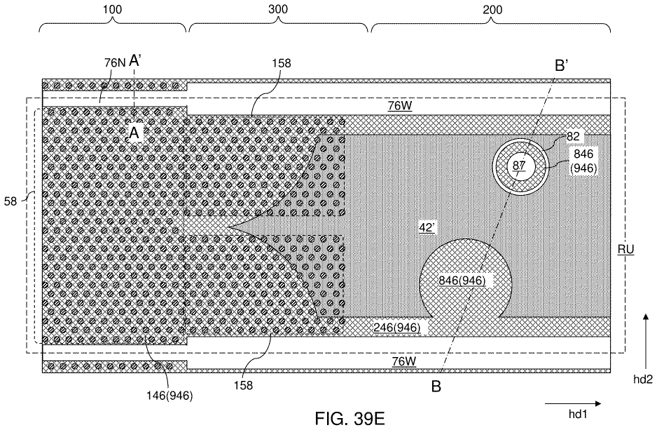

Referring to FIG. 39A-39E, a second alternative configuration of the second exemplary structure can be derived from the second exemplary structure by omitting formation of the access lateral isolation trenches 179. As a consequence, all structural components that are formed in the access lateral isolation trenches 179 in the second exemplary structure are absent in the second alternative configuration of the second exemplary structure. Further, each contact via structure 846 is in direct contact with only one lateral connection strip 246 that contacts a respective wide lateral isolation trench fill structure 76W.

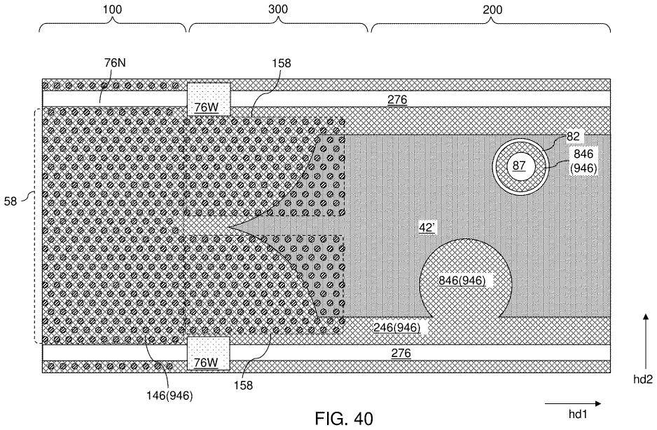

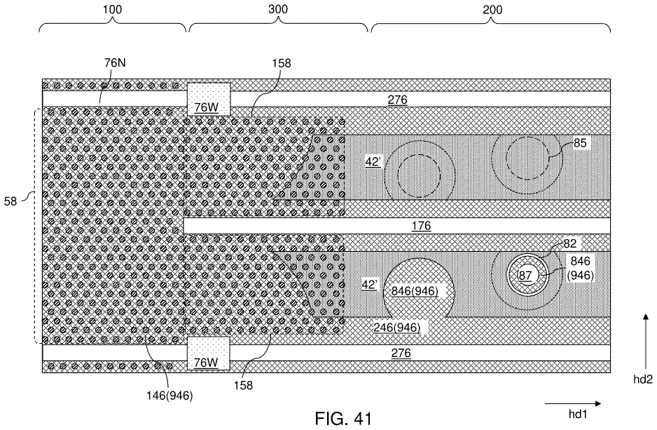

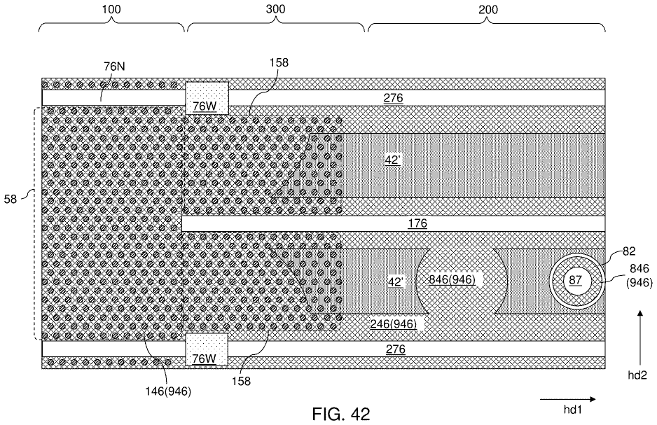

FIGS. 40, 41 and 42 are horizontal cross-sectional views of third, fourth and fifth alternative configurations of the second exemplary structure according to the second embodiment of the present disclosure. FIGS. 40, 41 and 42 are derived from FIGS. 39E, 38E and 37E, respectively. In the alternative configurations of FIGS. 40, 41 and 42, the wide lateral isolation trench fill structures 76W are formed separately from the narrow lateral isolation trench fill structures 76N as described above with respect to FIGS. 7A to 21E of the first embodiment. The wide lateral isolation trench fill structures 76W may be located in the connection region 300 and/or in the contact region 200. One or more of the wide lateral isolation trench fill structures 76W may be located at each boundary between adjacent memory blocks (e.g., repeating units RU).

In the alternative configurations of FIGS. 40, 41 and 42, the narrow lateral isolation trench sections 79N may be formed on two sides along the first horizontal direction (e.g., word line direction) hd1 of the wide lateral isolation trench section 79W that is filled with wide lateral isolation trench fill structure 76W. The narrow lateral isolation trench sections 79N in the memory array region 100 are filled with the narrow lateral isolation trench fill structures 76N, while the narrow lateral isolation trench sections 79N in the connection region 300 and/or the contact region 200 are filled with the additional lateral isolation trench fill structures 276. The narrow lateral isolation trench fill structures 76N and the additional lateral isolation trench fill structures 276 are formed at the same time.

The narrow lateral isolation trench fill structures 76N and the additional lateral isolation trench fill structures 276 may have the same width as each other or a different width from each other along the second horizontal direction (e.g., bit line direction) hd2. The narrow lateral isolation trench fill structures 76N and the additional lateral isolation trench fill structures 276 have a different (e.g., smaller) width along the second horizontal direction than the wide lateral isolation trench fill structures 76W. The narrow lateral isolation trench fill structure 76N contacts a first end of the wide lateral isolation trench fill structures 76W and the additional lateral isolation trench fill structure 276 contacts an opposing second end of the wide lateral isolation trench fill structures 76W along the first horizontal direction.

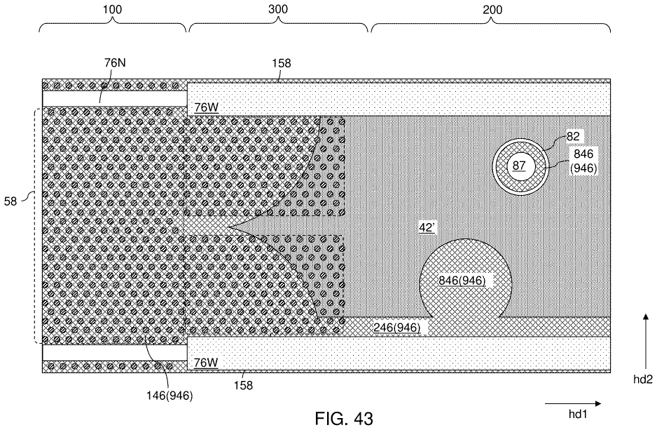

FIG. 43 is a horizontal cross-sectional view of the sixth alternative configuration of the second exemplary structure according to the second embodiment of the present disclosure that can be derived from the third alternative configuration shown in FIG. 40. In the sixth alternative configuration, the additional lateral isolation trench fill structures 276 are omitted and the wide lateral isolation trench fill structures 76W separate adjacent memory blocks in the connection regions 300 and the contact regions 200. In this configuration, the connection strips 246 are formed entirely through the contact via openings 85.

Referring to all drawings and according to various embodiments of the present disclosure, a memory device is provided, which comprises: integrated word line and contact via structures 946 each comprising a respective horizontally-extending word line 146, a respective contact via structure 846, and a respective lateral connection strip 246 connecting the respective horizontally-extending word line 146 and the respective contact via structure 846; insulating layers 32 vertically spaced apart from each other and interlaced with the horizontally-extending word lines 146 to provide a vertically alternating sequence (32, 146) of the insulating layers 32 and the horizontally-extending word lines 146; memory openings 49 vertically extending through the vertically alternating sequence (32, 146); and memory opening fill structures 58 located in the memory openings 49, wherein each of the memory opening fill structures 58 comprises a respective vertical stack of memory elements (which may comprise portions of memory material layers 54) located at levels of the horizontally-extending word lines 146 and a vertical semiconductor channel 60.

In one embodiment, the horizontally-extending word lines 146 laterally extend along a first horizontal direction hd1 and have a uniform word-line width along a second horizontal direction hd2 in a memory array region 100; the memory opening fill structures 58 are located in the memory array region 100; the lateral connection strips 246 laterally extend along the first horizontal direction hd1 and have a strip width along the second horizontal direction hd2 in a contact region 200, wherein the strip width is less than the uniform word line width; and the integrated word line and contact via structures 946 are located in the contact region 200.

In one embodiment, each of the horizontally-extending word lines 146 has a laterally-convex sidewall section in a connection region 300 that is located between the memory array region 100 and the contact region 200. In one embodiment, each of the horizontally-extending word lines 146 has a variable width that changes from the uniform word-line width to the strip width within the connection region 300 containing the laterally-convex sidewall sections.

In one embodiment, each of the contact via structures 846 has a respective bottom plate 846P and a respective tubular portion 846T having a bottom end that is connected to the respective bottom plate 846P. In one embodiment, a center portion of the respective bottom plate 846P has a uniform inner bottom plate thickness; the respective tubular portion 846T has a uniform lateral thickness between an inner sidewall and an outer sidewall; and the uniform lateral thickness is the same as the uniform inner bottom plate thickness.

In one embodiment, each of the tubular portions 846T of the contact via structures 846 laterally encloses a respective dielectric pillar material portion 87. In one embodiment, a contact-level dielectric layer 80 overlies the vertically alternating sequence (32, 146) and the tubular portions 846T. The contact-level dielectric layer 80 and the dielectric pillar material portions 87 are portions of a dielectric material having a uniform material composition throughout. In one embodiment, additional portions of the dielectric material comprise lateral isolation trench fill structures (76N, 76W, and/or 176) contacting sidewalls of each of the insulating layers 32 and each of the horizontally-extending word lines 146.

In one embodiment, the memory device further comprises metal oxide backside blocking dielectric layers 44 which continuously extend along surfaces of the horizontally-extending word lines 146, the lateral connection strips 246, the bottom plates 846P and the tubular portions 846T.

In one embodiment, the memory device further comprises: additional integrated word line and contact via structures 946 comprising a respective additional horizontally-extending word line 146, a respective additional contact via structure 846, and a respective additional lateral connection strip 246. The additional integrated word line and contact via structures 946 are located in a second memory block (e.g., additional repeating unit RU) which is laterally spaced along the second horizontal direction hd1 from a first memory block (e.g., the repeating unit RU) containing the integrated word line and contact via structures 946 and the vertically alternating sequence of the insulating layers 32 and the horizontally-extending word lines 146. The memory device further comprises additional insulating layers 32 vertically spaced apart from each other and interlaced with the additional horizontally-extending word lines 146 to provide an additional vertically alternating sequence (32, 146) of the additional insulating layers 32 and the additional horizontally-extending word lines 146 located in the second memory block. The memory device further comprises a dual-width lateral isolation trench 79 extending along the first horizontal direction hd1 and laterally separating the first memory block from the second memory block, wherein the dual-width lateral isolation trench comprises a wide lateral isolation trench section 79W having a first width and located in the contact region 200 and further comprising a narrow lateral isolation trench section 79N having a second width and located in the memory array region 100, the first width being greater than the second width. A wide lateral isolation trench fill structure 76W fills the wide lateral isolation trench section 79W; and a narrow lateral isolation trench fill structure 76N fills the narrow lateral isolation trench section.

In the first embodiment, the narrow lateral isolation trench fill structure 76N comprises a part of a continuous dielectric material portion that has a uniform material composition throughout and further comprises a contact-level dielectric layer 80 overlying the vertically alternating sequence and the additional vertically alternating sequence; and the wide lateral isolation trench fill structure 76W is not part of the continuous dielectric material portion.

In the second embodiment, the narrow lateral isolation trench fill structure 76N and the wide lateral isolation structure 76W both comprise parts of a continuous dielectric material portion that has a uniform material composition throughout and further comprises a contact-level dielectric layer 80 overlying the vertically alternating sequence and the additional vertically alternating sequence.

In one embodiment, the lateral connection strips 246 of the integrated word line and contact via structures 946 are in contact with a sidewall of the wide lateral isolation trench fill structure 76W.

In the embodiments of FIG. 40-42, an additional lateral isolation trench fill structure 276 contacts a first end of the wide lateral isolation trench fill structure 76W, and the narrow lateral isolation trench fill structure 76N contacts a second end of the wide lateral isolation trench fill structure 76W opposite to the first end. The wide lateral isolation trench fill structure 76W has a greater width along the second horizontal direction hd2 than the narrow lateral isolation trench fill structure 76N and the additional lateral isolation trench fill structure 276.

In various embodiments, the memory device also comprises: an access lateral isolation trench 179 that is laterally spaced from the dual-width lateral isolation trench 79 along the second horizontal direction hd2; and an access isolation trench fill structure 176 filling the access lateral isolation trench 179. The lateral connection strips 246 of the integrated word line and contact via structures 946 are in contact with a sidewall of the access isolation trench fill structure 176. In one embodiment shown in FIG. 38A-38E, plural rows of the integrated word line and contact via structures 946 extending along the first horizontal direction are located between the access isolation trench 179 and the dual-width isolation trench 79.

In one embodiment, each of the integrated word line and contact via structures 946 comprises at least one electrically conductive material having a unform material composition throughout and is free of any material interface therein. In one embodiment, a vertical stack of dielectric material plates 42′ may be vertically interlaced with the insulating layers 32. Each of the dielectric material plates 42′ is in contact with a sidewall of the horizontally-extending word line 146, a sidewall of the lateral connection strip 246, and a sidewall of the contact via structure 846 of a respective one of the integrated word line and contact via structures 946.

Although the foregoing refers to particular preferred embodiments, it will be understood that the claims are not so limited. It will occur to those of ordinary skill in the art that various modifications may be made to the disclosed embodiments and that such modifications are intended to be within the scope of the claims. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Where an embodiment using a particular structure and/or configuration is illustrated in the present disclosure, it is understood that the claims may be practiced with any other compatible structures and/or configurations that are functionally equivalent provided that such substitutions are not explicitly forbidden or otherwise known to be impossible to one of ordinary skill in the art. All of the publications, patent applications and patents cited herein are incorporated herein by reference in their entirety.

1. A memory device, comprising:
integrated word line and contact via structures each comprising a respective horizontally-extending word line, a respective contact via structure, and a respective lateral connection strip connecting the respective horizontally-extending word line and the respective contact via structure;
insulating layers vertically spaced apart from each other and interlaced with the horizontally-extending word lines to provide a vertically alternating sequence of the insulating layers and the horizontally-extending word lines;
memory openings vertically extending through the vertically alternating sequence; and
memory opening fill structures located in the memory openings, wherein each of the memory opening fill structures comprises a respective vertical stack of memory elements located at levels of the horizontally-extending word lines and a vertical semiconductor channel.

2. The memory device of claim 1, wherein:
the horizontally-extending word lines laterally extend along a first horizontal direction and have a uniform word-line width along a second horizontal direction in a memory array region;
the memory opening fill structures are located in the memory array region;
the lateral connection strips laterally extend along the first horizontal direction and have a strip width along the second horizontal direction in a contact region, wherein the strip width is less than the uniform word line width; and
the integrated word line and contact via structures are located in the contact region.

3. The memory device of claim 2, wherein:
each of the horizontally-extending word lines has a laterally-convex sidewall section in a connection region that is located between the memory array region and the contact region; and
each of the horizontally-extending word lines has a variable width that changes from the uniform word-line width to the strip width within the connection region containing the laterally-convex sidewall sections.

4. The memory device of claim 1, wherein each of the contact via structures has a respective bottom plate and a respective tubular portion having a bottom end that is connected to the respective bottom plate.

5. The memory device of claim 4, wherein:
a center portion of the respective bottom plate has a uniform inner bottom plate thickness;
the respective tubular portion has a uniform lateral thickness between an inner sidewall and an outer sidewall;
the uniform lateral thickness is the same as the uniform inner bottom plate thickness; and
each of the tubular portions of the contact via structures laterally encloses a respective dielectric pillar material portion.

6. The memory device of claim 5, further comprising a contact-level dielectric layer overlying the vertically alternating sequence and the tubular portions, wherein the contact-level dielectric layer and the dielectric pillar material portions are portions of a dielectric material having a uniform material composition throughout, and wherein additional portions of the dielectric material comprise lateral isolation trench fill structures contacting sidewalls of each of the insulating layers and each of the horizontally-extending word lines.

7. The memory device of claim 4, further comprising metal oxide backside blocking dielectric layers which continuously extend along surfaces of the horizontally-extending word lines, the lateral connection strips, the bottom plates and the tubular portions.

8. The memory device of claim 2, further comprising:
additional integrated word line and contact via structures each comprising a respective additional horizontally-extending word line, a respective additional contact via structure, and a respective additional lateral connection strip located in a second memory block which is laterally spaced along the second horizontal direction from a first memory block containing the integrated word line and contact via structures and the vertically alternating sequence of the insulating layers and the horizontally-extending word lines;
additional insulating layers vertically spaced apart from each other and interlaced with the additional horizontally-extending word lines to provide an additional vertically alternating sequence of the additional insulating layers and the additional horizontally-extending word lines located in the second memory block;
a dual-width lateral isolation trench extending along the first horizontal direction and laterally separating the first memory block from the second memory block, wherein the dual-width lateral isolation trench comprises a wide lateral isolation trench section having a first width and located in the contact region, and further comprises a narrow lateral isolation trench section having a second width and located in the memory array region, the first width being greater than the second width;
a wide lateral isolation trench fill structure which fills the wide lateral isolation trench section; and
a narrow lateral isolation trench fill structure which fills the narrow lateral isolation trench section.

9. The memory device of claim 8, wherein the lateral connection strips of the integrated word line and contact via structures are in contact with a sidewall of the wide lateral isolation trench fill structure.

10. The memory device of claim 8, wherein:
the narrow lateral isolation trench fill structure comprises a part of a continuous dielectric material portion that has a uniform material composition throughout and further comprises a contact-level dielectric layer overlying the vertically alternating sequence and the additional vertically alternating sequence; and
the wide lateral isolation trench fill structure is not part of the continuous dielectric material portion.

11. The memory device of claim 8, wherein the narrow lateral isolation trench fill structure and the wide lateral isolation structure both comprise parts of a continuous dielectric material portion that has a uniform material composition throughout and further comprises a contact-level dielectric layer overlying the vertically alternating sequence and the additional vertically alternating sequence.

12. The memory device of claim 8, further comprising an additional lateral isolation trench fill structure which contacts a first end of the wide lateral isolation trench fill structure.

13. The memory device of claim 12, wherein:
the narrow lateral isolation trench fill structure contacts a second end of the wide lateral isolation trench fill structure opposite to the first end; and
the wide lateral isolation trench fill structure has a greater width along the second horizontal direction than the narrow lateral isolation trench fill structure and the additional lateral isolation trench fill structure.

14. The memory device of claim 8, further comprising:
an access lateral isolation trench that is laterally spaced from the dual-width lateral isolation trench along the second horizontal direction; and
an access isolation trench fill structure filling the access lateral isolation trench, wherein the lateral connection strips of the integrated word line and contact via structures are in contact with a sidewall of the access isolation trench fill structure.

15. The memory device of claim 14, wherein plural rows of the integrated word line and contact via structures extending along the first horizontal direction are located between the access isolation trench and the dual-width isolation trench.

16. The memory device of claim 1, wherein each of the integrated word line and contact via structures comprises at least one electrically conductive material having a unform material composition throughout and is free of any material interface therein.

17. The memory device of claim 1, further comprising a vertical stack of dielectric material plates vertically interlaced with the insulating layers, wherein each of the dielectric material plates is in contact with a sidewall of the horizontally-extending word line, a sidewall of the lateral connection strip, and a sidewall of the contact via structure of a respective one of the integrated word line and contact via structures.

18. A method of forming a memory device, comprising:
forming an alternating stack of insulating layers and sacrificial material layers over a substrate;
forming memory openings through the alternating stack;
forming memory opening fill structures in the memory openings, wherein each of the memory opening fill structures comprises a respective vertical stack of memory elements and a vertical semiconductor channel;
forming dual-width lateral isolation trenches through the alternating stack, wherein each of the dual-width lateral isolation trenches comprises a respective wide lateral isolation trench section having a first width and a narrow lateral isolation trench section having a second width, the first width being greater than the second width;
forming contact via cavities such that a top surface of a respective one of the sacrificial material layers is exposed underneath each of the contact via cavities;
performing a first isotropic etch process that isotropically recesses the sacrificial material layers employing the narrow lateral isolation trench sections as first conduits for a first isotropic etchant;
performing a second isotropic etch process that isotropically recesses the sacrificial material layers employing the contact via cavities and employing at least one of the wide lateral isolation trench sections or access lateral isolation trenches as second conduits for a second isotropic etchant; and
forming integrated word line and contact via structures in cavities that are formed by the first isotropic etch process and the second isotropic etch process, wherein each of the integrated word line and contact via structures comprises a respective horizontally-extending word line, a respective contact via structure, and a respective lateral connection strip connecting the respective horizontally-extending word line and the respective contact via structure.

19. The method of claim 18, further comprising forming wide lateral isolation trench fill structures by filling the wide lateral isolation trench sections with a dielectric fill material prior to performing the first isotropic etch process.

20. The method of claim 18, wherein:
the access lateral isolation trenches are formed simultaneously with formation of the dual-width lateral isolation trenches; and
the dual-width lateral isolation trenches are interlaced with the access lateral isolation trenches.
